(19) United States
(12) Patent Application Publication
(10) Pub. No.: US 2026/0013200 A1
(43) Pub. Date: Jan. 8, 2026

(54) SEMICONDUCTOR DEVICES AND METHODS OF FORMING THE SAME

(71) Applicant: Taiwan Semiconductor Manufacturing Co., Ltd, Hsinchu (TW)

(72) Inventors: Po-Kang Ho, Taoyuan City (TW); Tsai-Yu Huang, Taoyuan City (TW); Chien-Hao Chen, Chuangwei Township (TW)

(21) Appl. No.: 18/950,516

(22) Filed: Nov. 18, 2024

Related U.S. Application Data
(60) Provisional application No. 63/667,183, filed on Jul. 3, 2024.

(51) Int. Cl. H01L 29/417; H01L 29/06; H01L 29/423; H01L 29/66; H01L 29/775; H01L 29/786

(52) U.S. Cl. CPC H10D 64/258; H10D 62/116; H10D 64/518; H10D 30/014; H10D 30/43; H10D 30/6735; H10D 30/6757; H10D 62/121

(57) ABSTRACT

A semiconductor device and the method of forming the same are provided. The semiconductor device may include a first source/drain region, a first nanostructure adjacent the first source/drain region, a second source/drain region, a second nanostructure adjacent the second source/drain region, a gate structure, a spacer, and a dielectric layer. The gate structure may include a gate electrode and a gate dielectric. A first portion of the gate electrode and a first portion of the gate dielectric may be between the first nanostructure and the second nanostructure. A first portion of the spacer may be between the first source/drain region and the second source/drain region. A first portion of the dielectric layer may be between the first portion of the gate dielectric and the first portion of the spacer. The dielectric layer may include a different material from the gate dielectric and the spacer.

### PRIORITY CLAIM AND CROSS-REFERENCE

This application claims the benefit of U.S. Provisional Application No. 63/667,183, filed on Jul. 3, 2024, which application is hereby incorporated herein by reference.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of nanostructure field-effect transistors (nano-FETs) in a three-dimensional view, in accordance with some embodiments.

FIGS. 2, 3, 4, 5, 6A, 6B, 6C, 6D, 6E, 7A, 7B, 7C, 7D, 7E, 8A, 8B, 8C, 8D, 8E, 9A, 9B, 9C, 9D, 9E, 10A, 10B, 10C, 10D, 10E, 11A, 11B, 11C, 11D, 11E, 11F, 12A, 12B, 12C, 12D, 12E, 12F, 12G, 13A, 13B, 13C, 13D, 13E, 14A, 14B, 14C, 15A, 15B, 15C, 15D, 15E, 16A, 16B, 16C, 16D, 16E, 17A, 17B, 17C, 17D, 17E, 17F, 17G, 18A, 18B, 18C, 19A, 19B, 19C, 20A, 20B, and 20C are views of intermediate steps in the manufacturing of a semiconductor device including nano-FETs, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Various embodiments provide semiconductor devices, such as nano-FETs, and methods of forming the same. The methods may include forming additional dielectric layers between the gate electrodes and the source/drain regions by converting portions of dummy gates for the devices into dielectric layers before forming gate spacers or removing the remaining dummy gates. Due to the dielectric layers (in addition to the gate spacers), the gate electrodes may be disposed further away from the source/drain regions and increased electrical insulation may be achieved between the gate electrodes and the source/drain regions. As a result, the risk of electrical leakage and parasitic capacitance between the gate electrodes and the source/drain regions may be decreased, thereby improving the performance and reliability of the semiconductor devices.

Some embodiments discussed herein are described in the context of a semiconductor device including nano-FETs. However, various embodiments may be applied to dies including other types of transistors (e.g., fin field effect transistors (FinFETs), vertical field-effect transistors (VFETs), complementary field-effect transistors (CFETs), planar transistors, or the like) in lieu of or in combination with the nano-FETs.

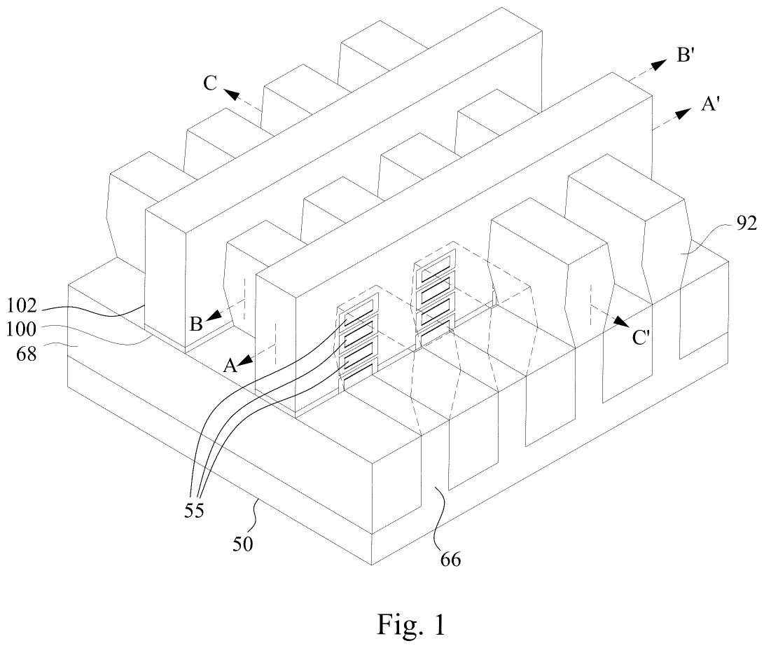

FIG. 1 illustrates an example of nano-FETs (e.g., nanowire FETs, nanosheet FETs, or the like) in a three-dimensional view. The nano-FETs comprise nanostructures 55 (e.g., nanosheets, nanowires, or the like) over fins 66 on a substrate 50 (e.g., a semiconductor substrate), wherein the nanostructures 55 act as channel regions for the nano-FETs. The nanostructures 55 may include p-type nanostructures, n-type nanostructures, or a combination thereof. Shallow trench isolation (STI) regions 68 are disposed between adjacent fins 66, which may protrude above and from between neighboring STI regions 68. Although the STI regions 68 are described/illustrated as being separate from the substrate 50, as used herein, the term “substrate” may refer to the semiconductor substrate alone or a combination of the semiconductor substrate and the STI regions. Additionally, although bottom portions of the fins 66 are illustrated as being single, continuous materials with the substrate 50, the bottom portions of the fins 66 and/or the substrate 50 may comprise a single material or a plurality of materials. In this context, the fins 66 refer to the portions extending between the neighboring STI regions 68.

Gate dielectrics 100 are over top surfaces of the fins 66 and along top surfaces, sidewalls, and bottom surfaces of the nanostructures 55. Gate electrodes 102 are over the gate dielectrics 100. Epitaxial source/drain regions 92 are disposed on the fins 66 on opposing sides of the gate dielectrics 100 and the gate electrodes 102. Source/drain region(s) 92 may refer to a source or a drain, individually or collectively dependent upon the context.

FIG. 1 further illustrates reference cross-sections that are used in later figures. Reference cross-section A-A′ is along a longitudinal axis of a gate electrode 102 and in a direction, for example, perpendicular to the direction of current flow between the epitaxial source/drain regions 92 of a nano-FET. Reference cross-section B-B′ is parallel to the reference cross-section A-A′ and extends through epitaxial source/drain regions 92 of multiple nano-FETs. Reference cross-section C-C′ is perpendicular to the reference cross-section A-A′ and is parallel to a longitudinal axis of a fin 66 of the nano-FET and in a direction of, for example, a current flow between the epitaxial source/drain regions 92 of the nano-FET. Subsequent figures refer to these reference cross-sections for clarity. Some embodiments discussed herein are discussed in the context of nano-FETs formed using a gate-last process. In other embodiments, a gate-first process may be used. Also, some embodiments contemplate aspects used in planar devices, such as planar FETs or in FinFETs.

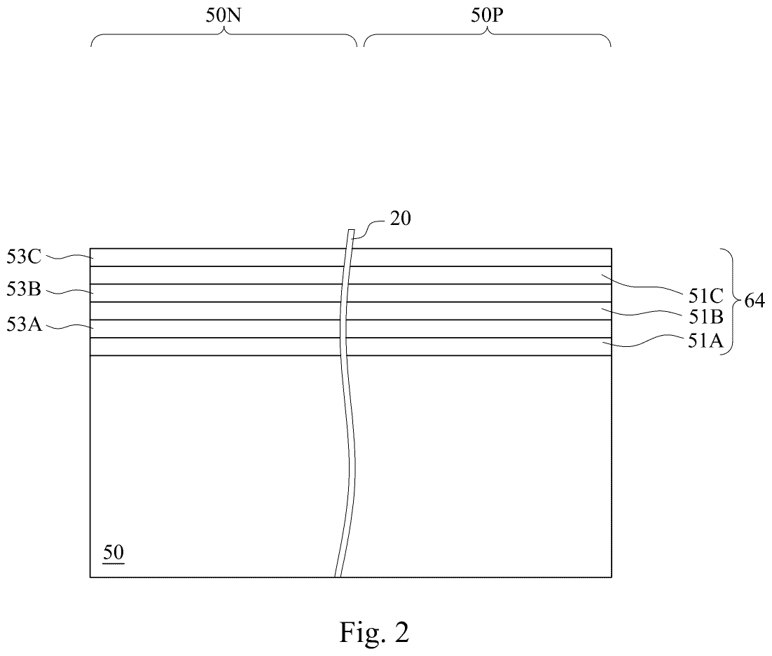

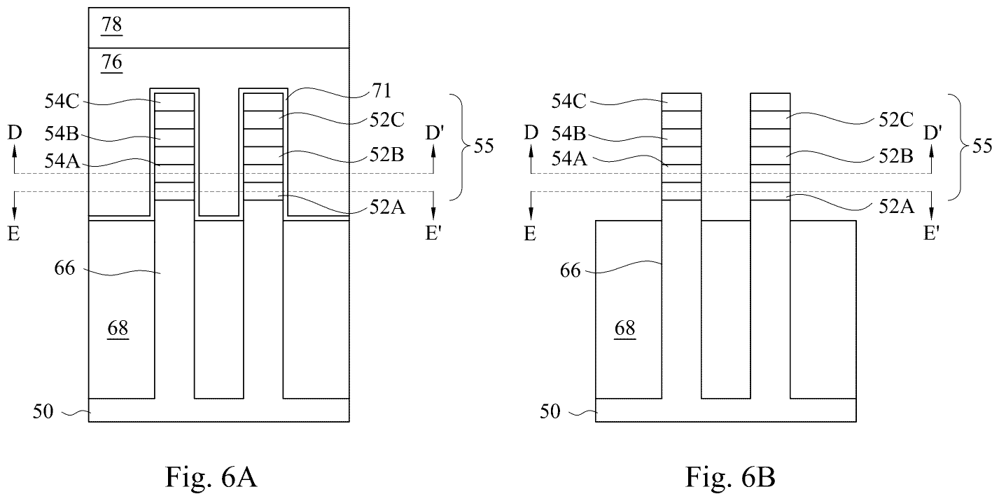

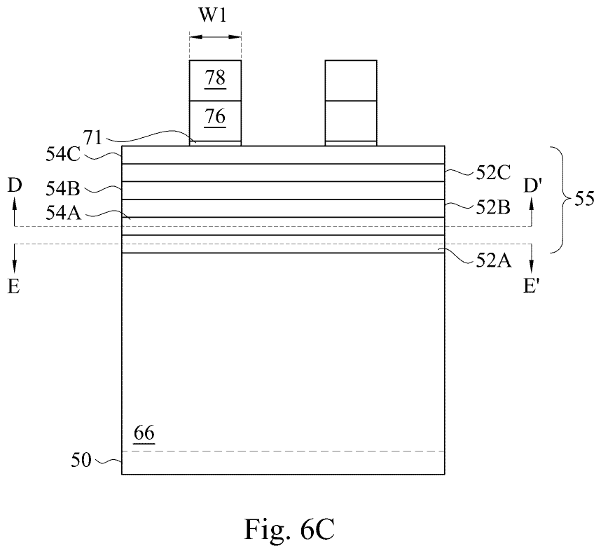

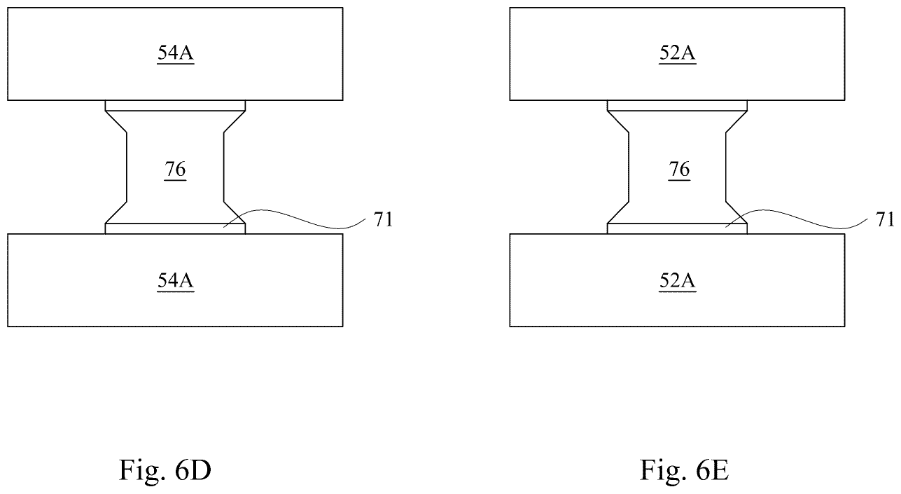

FIGS. 2 through 20C are views of intermediate steps in the manufacturing of a semiconductor device including nano-FETs, in accordance with some embodiments. FIGS. 2, 3, 4, 5, 6A, 7A, 8A, 9A, 10A, 11A, 12A, 13A, 14A, 15A, 16A, 17A, 18A, 19A, and 20A illustrate cross-sectional views along the reference cross-section A-A′ illustrated in FIG. 1. FIGS. 6B, 7B, 8B, 9B, 10B, 11B, 12B, 12F, 13B, 14B, 15B, 16B, 17B, 18B, 19B, and 20B illustrate cross-sectional views along the reference cross-section B-B′ illustrated in FIG. 1. FIGS. 6C, 7C, 8C, 9C, 10C, 11C, 11F, 12C, 12G, 13C, 14C, 15C, 16C, 17C, 18C, 19C, and 20C illustrate cross-sectional views along the reference cross-section C-C′ illustrated in FIG. 1.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

The substrate 50 has an n-type region 50N and a p-type region 50P. The n-type region 50N can be for forming n-type devices, such as NMOS transistors, e.g., n-type nano-FETs, and the p-type region 50P can be for forming p-type devices, such as PMOS transistors, e.g., p-type nano-FETs. The n-type region 50N may be physically separated from the p-type region 50P (as illustrated by divider 20), and any number of device features (e.g., other active devices, doped regions, isolation structures, etc.) may be disposed between the n-type region 50N and the p-type region 50P. Although one n-type region 50N and one p-type region 50P are illustrated, any number of n-type regions 50N and p-type regions 50P may be provided.

Further in FIG. 2, a multi-layer stack 64 is formed over the substrate 50. The multi-layer stack 64 includes alternating layers of first semiconductor layers 51A-51C (collectively referred to as first semiconductor layers 51) and second semiconductor layers 53A-53C (collectively referred to as second semiconductor layers 53). For purposes of illustration and as discussed in greater detail below, the first semiconductor layers 51 will be removed and the second semiconductor layers 53 will be patterned to form channel regions of nano-FETs in the n-type region 50N and the p-type region 50P. However, in some embodiments the first semiconductor layers 51 may be removed and the second semiconductor layers 53 may be patterned to form channel regions of nano-FETs in the n-type region 50N, and the second semiconductor layers 53 may be removed and the first semiconductor layers 51 may be patterned to form channel regions of nano-FETs in the p-type region 50P. In some embodiments the second semiconductor layers 53 may be removed and the first semiconductor layers 51 may be patterned to form channel regions of nano-FETs in the n-type region 50N, and the first semiconductor layers 51 may be removed and the second semiconductor layers 53 may be patterned to form channel regions of nano-FETs in the p-type region 50P. In some embodiments, the second semiconductor layers 53 may be removed and the first semiconductor layers 51 may be patterned to form channel regions of nano-FETs in both the n-type region 50N and the p-type region 50P.

The multi-layer stack 64 is illustrated as including three layers of each of the first semiconductor layers 51 and the second semiconductor layers 53 for illustrative purposes. In some embodiments, the multi-layer stack 64 may include any number of the first semiconductor layers 51 and the second semiconductor layers 53. Each of the layers of the multi-layer stack 64 may be epitaxially grown using a process such as chemical vapor deposition (CVD), atomic layer deposition (ALD), vapor phase epitaxy (VPE), molecular beam epitaxy (MBE), or the like. In various embodiments, the first semiconductor layers 51 may be formed of a first semiconductor material, such as silicon germanium or the like, and the second semiconductor layers 53 may be formed of a second semiconductor material different from the first semiconductor material, such as silicon, carbon-doped silicon, or the like.

The first semiconductor materials and the second semiconductor materials may be materials having a high etch selectivity to one another. As such, the first semiconductor layers 51 of the first semiconductor material may be removed without significantly removing the second semiconductor layers 53 of the second semiconductor material thereby allowing the second semiconductor layers 53 to be patterned to form channel regions of nano-FETs. Similarly, in embodiments in which the second semiconductor layers 53 are removed and the first semiconductor layers 51 are patterned to form channel regions, the second semiconductor layers 53 of the second semiconductor material may be removed without significantly removing the first semiconductor layers 51 of the first semiconductor material, thereby allowing the first semiconductor layers 51 to be patterned to form channel regions of nano-FETs.

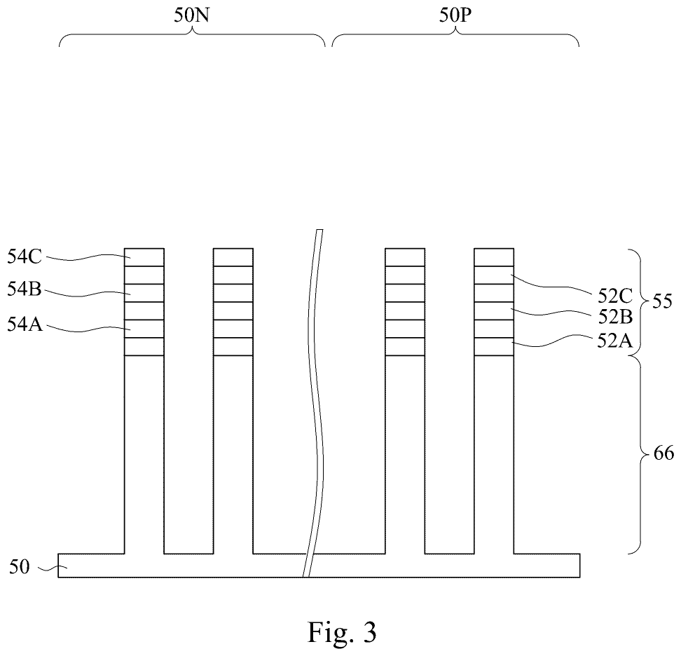

In FIG. 3, fins 66 are formed in the substrate 50 and nanostructures 55 are formed in the multi-layer stack 64, in accordance with some embodiments. In some embodiments, the nanostructures 55 and the fins 66 may be formed in the multi-layer stack 64 and the substrate 50, respectively, by etching trenches in the multi-layer stack 64 and the substrate 50. The etching may be any acceptable etch process, such as a reactive ion etch (RIE), neutral beam etch (NBE), the like, or a combination thereof. The etching may be anisotropic. Forming the nanostructures 55 by etching the multi-layer stack 64 may further define first nanostructures 52A-52C (collectively referred to as the first nanostructures 52) from the first semiconductor layers 51 and define second nanostructures 54A-54C (collectively referred to as the second nanostructures 54) from the second semiconductor layers 53. The first nanostructures 52 and the second nanostructures 54 may be collectively referred to as nanostructures 55.

The fins 66 and the nanostructures 55 may be patterned by any suitable method. For example, the fins 66 and the nanostructures 55 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins 66.

FIG. 3 illustrates the fins 66 in the n-type region 50N and the p-type region 50P as having substantially equal widths for illustrative purposes. In some embodiments, widths of the fins 66 in the n-type region 50N may be greater or thinner than the fins 66 in the p-type region 50P. Further, while each of the fins 66 and the nanostructures 55 are illustrated as having a consistent width throughout, in other embodiments, the fins 66 and/or the nanostructures 55 may have tapered sidewalls such that a width of each of the fins 66 and/or the nanostructures 55 continuously increases in a direction towards the substrate 50. In such embodiments, each of the nanostructures 55 may have a different width and be trapezoidal in shape.

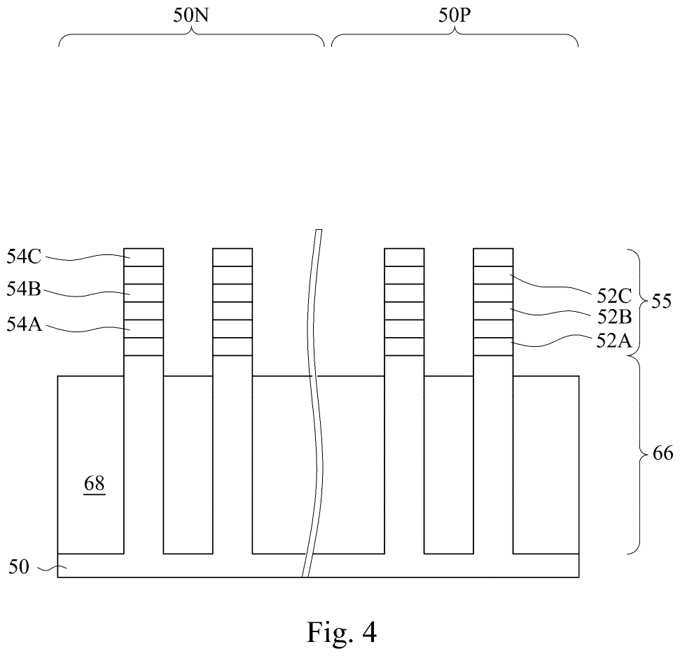

In FIG. 4, shallow trench isolation (STI) regions 68 are formed adjacent the fins 66. The STI regions 68 may be formed by depositing an insulation material over the substrate 50, the fins 66, and nanostructures 55, and between adjacent fins 66. The insulation material may be an oxide, such as silicon oxide, a nitride, the like, or a combination thereof, and may be formed by high-density plasma CVD (HDP-CVD), flowable CVD (FCVD), the like, or a combination thereof. Other insulation materials formed by any acceptable process may be used. In the illustrated embodiment, the insulation material is silicon oxide formed by an FCVD process. An anneal process may be performed once the insulation material is formed. In an embodiment, the insulation material is formed such that excess insulation material covers the nanostructures 55. Although the insulation material is illustrated as a single layer, some embodiments may utilize multiple layers. For example, in some embodiments a liner (not separately illustrated) may first be formed along a surface of the substrate 50, the fins 66, and the nanostructures 55. Thereafter, a fill material, such as those discussed above may be formed over the liner.

A removal process is then applied to the insulation material to remove excess insulation material over the nanostructures 55. In some embodiments, a planarization process such as a chemical mechanical polish (CMP), an etch-back process, combinations thereof, or the like may be utilized. The planarization process exposes the nanostructures 55 such that top surfaces of the nanostructures 55 and the insulation material may be substantially co-planar or level after the planarization process is complete.

The insulation material is then recessed to form the STI regions 68. The insulation material is recessed such that upper portions of fins 66 in the n-type region 50N and the p-type region 50P protrude from between neighboring STI regions 68. Further, the top surfaces of the STI regions 68 may have a flat surface as illustrated, a convex surface, a concave surface (such as dishing), or a combination thereof. The top surfaces of the STI regions 68 may be formed flat, convex, and/or concave by an appropriate etch. The STI regions 68 may be recessed using an acceptable etching process, such as one that is selective to the material of the insulation material (e.g., etches the material of the insulation material at a faster rate than the material of the fins 66 and the nanostructures 55). For example, an oxide removal using, for example, dilute hydrofluoric acid may be used. Thereafter, an optional hard mask (not separately illustrated) may be formed over the top surfaces of the STI regions 68 to cover the STI regions 68. The hard mask may be made of a nitride or other material that has etch selectivity to the STI regions 68 (e.g., etch selectivity to a fill material of the STI regions 68).

The process described above with respect to FIGS. 2 through 4 is one example of how the fins 66 and the nanostructures 55 may be formed. In some embodiments, the fins 66 and/or the nanostructures 55 may be formed using a mask and an epitaxial growth process. For example, a dielectric layer can be formed over a top surface of the substrate 50, and trenches can be etched through the dielectric layer to expose the underlying substrate 50. Epitaxial structures can be epitaxially grown in the trenches, and the dielectric layer can be recessed such that the epitaxial structures protrude from the dielectric layer to form the fins 66 and/or the nanostructures 55. The epitaxial structures may comprise the alternating semiconductor materials discussed above, such as the first semiconductor materials and the second semiconductor materials. In some embodiments where epitaxial structures are epitaxially grown, the epitaxially grown materials may be in situ doped during growth, which may obviate prior and/or subsequent implantations, although in situ and implantation doping may be used together.

Additionally, the first semiconductor layers 51 (and resulting first nanostructures 52) and the second semiconductor layers 53 (and resulting second nanostructures 54) are illustrated and discussed herein as comprising the same materials in the p-type region 50P and the n-type region 50N for illustrative purposes. In some embodiments, one or both of the first semiconductor layers 51 and the second semiconductor layers 53 may be different materials or formed in a different order in the p-type region 50P and the n-type region 50N.

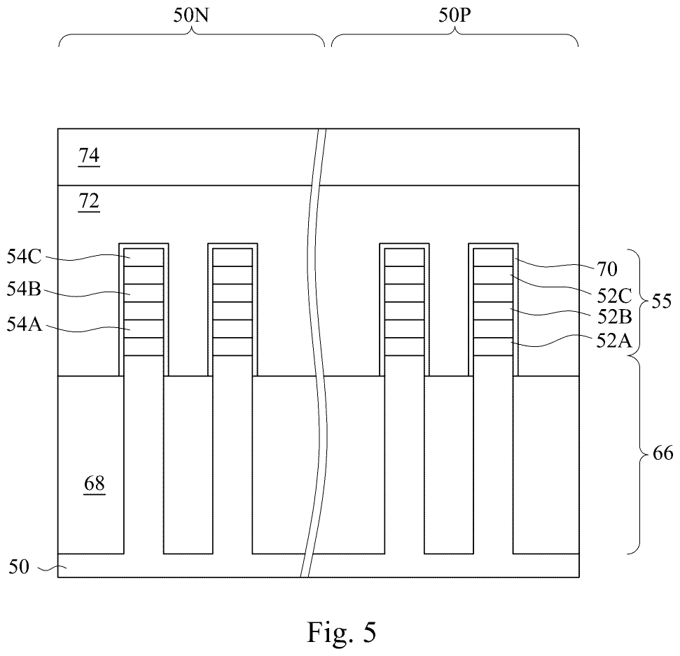

In FIG. 5, a dummy dielectric layer 70 is formed on the fins 66, the nanostructures 55, and/or the STI regions 68. The dummy dielectric layer 70 may be silicon oxide, silicon carbide, silicon nitride, a combination thereof, or the like, and may be formed by a suitable deposition process. A dummy gate layer 72 is formed over the dummy dielectric layer 70, and a mask layer 74 is formed over the dummy gate layer 72. The dummy gate layer 72 may be deposited over the dummy dielectric layer 70 and then planarized, such as by a CMP. The mask layer 74 may be deposited over the dummy gate layer 72. The dummy gate layer 72 may be a conductive or non-conductive material and may be selected from a group including amorphous silicon, polycrystalline silicon (polysilicon), polycrystalline silicon germanium (poly-SiGe), metallic nitrides, metallic silicides, metallic oxides, and metals. The dummy gate layer 72 may be deposited by physical vapor deposition (PVD), CVD, sputter deposition, or other techniques for depositing the selected material. The dummy gate layer 72 may be made of other materials that have a high etching selectivity from the etching of isolation regions. The mask layer 74 may include, for example, silicon nitride, silicon oxynitride, or the like. In this example, a single dummy gate layer 72 and a single mask layer 74 are formed across the n-type region 50N and the p-type region 50P.

FIGS. 6A through 20C illustrate cross-sectional and top-down views of various additional steps in the manufacturing of the semiconductor device including nano-FETs, in accordance to some embodiments. FIGS. 6A through 20C illustrate features in either the n-type region 50N or the p-type region 50P unless specified otherwise.

In FIGS. 6A through 6E, masks 78, dummy gates 76, and dummy gate dielectrics 71 are formed. The dummy gates 76 and dummy gate dielectrics 71 may be collectively referred to as dummy gate structures. FIG. 6D illustrates a top-down view of a portion of the structure illustrated in FIGS. 6A, 6B, and 6C, including the second nanostructures 54A, along the reference cross-sections D-D′. FIG. 6E illustrates a top-down view of a portion of the structure illustrated in FIGS. 6A, 6B, and 6C, including the first nanostructure 52A, along the reference cross-sections E-E′. The following discussion uses a top-down view of the second nanostructure 54A as an example of the second nanostructures 54 and a top-down view of the first nanostructure 52A over a same fin 66 as an example of the first nanostructures 52. Same or similar shapes, dimensions, and properties may also apply to other second nanostructures 54 and first nanostructures 52.

The mask layer 74 (see FIG. 5) may be patterned using suitable photolithography and etching processes to form the masks 78. The pattern of the masks 78 then may be transferred to the dummy gate layer 72 and to the dummy dielectric layer 70 to form the dummy gates 76 and the dummy gate dielectrics 71, respectively, using suitable etching processes. The dummy gates 76 cover respective channel regions of the fins 66. The pattern of the masks 78 may be used to physically separate each of the dummy gates 76 from adjacent dummy gates 76. The dummy gates 76 may also have a lengthwise direction substantially perpendicular to the lengthwise direction of respective fins 66.

As shown in FIG. 6C, portions of the dummy gates 76 over the nanostructures 55 may have a width W₁ in a range from about 10 nm to about 15 nm, such as about 13 nm. As shown in FIGS. 6D and 6E, after the etching processes, the dummy gate 76 may have concave sidewalls in the top-down view. A width of a portion of the dummy gate 76 (in the top-down view) between neighboring first nanostructures 52A may decrease as the dummy gate 76 extends away from the corresponding dummy gate dielectric 71. A width of a portion of the dummy gate 76 (in the top-down view) between neighboring second nanostructures 54A may decrease as the dummy gate 76 extends away from the corresponding dummy gate dielectric 71.

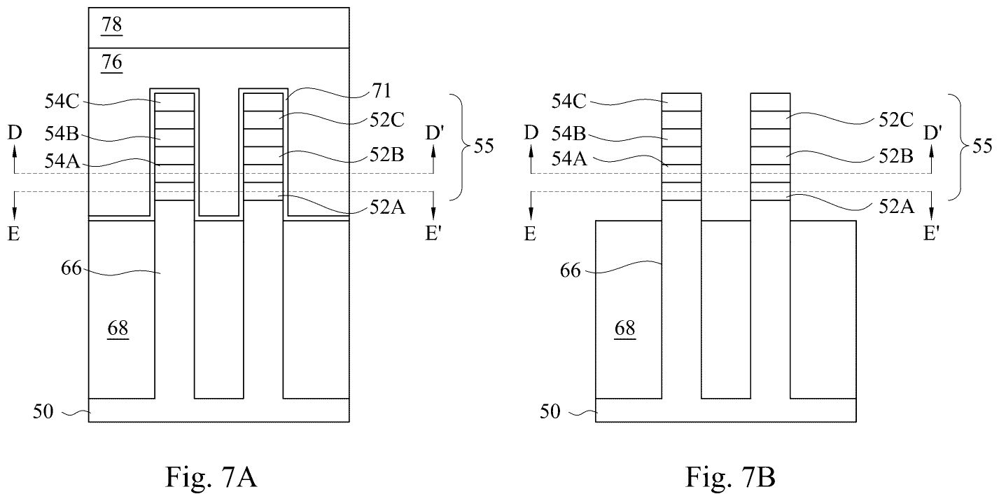

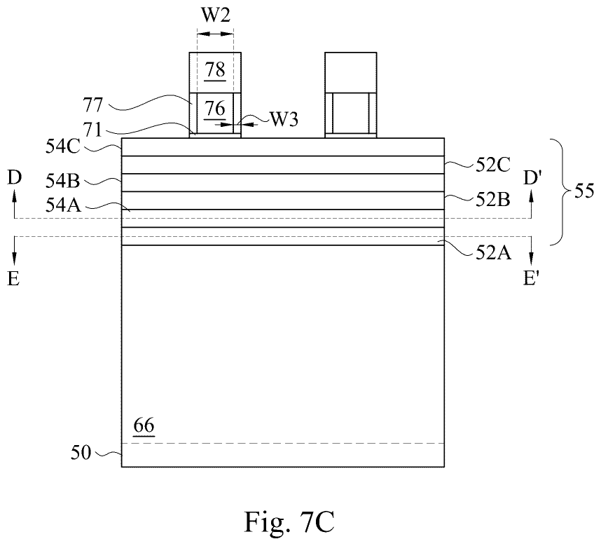

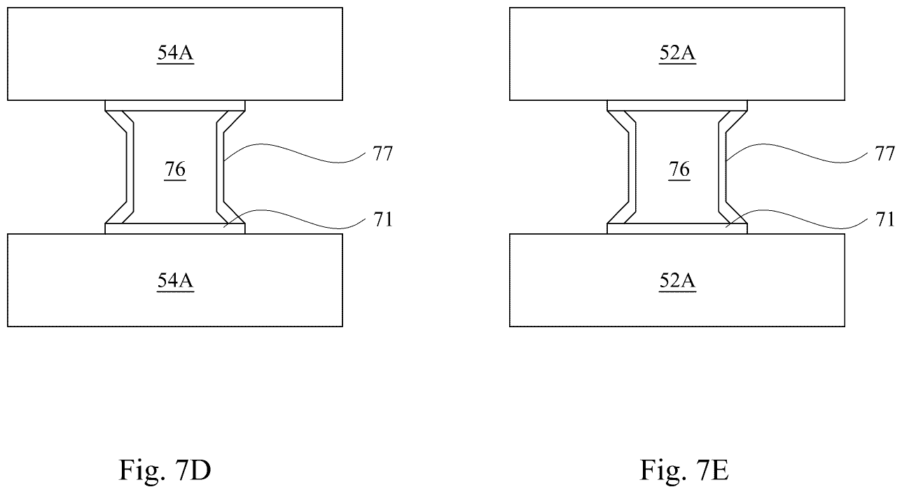

In FIGS. 7A through 7E, portions of the dummy gates 76 at sidewalls of the dummy gates 76 are converted to dielectric layers 77. The dielectric layers 77 may lead to increased distance and electrical insulation between subsequently formed source/drain regions and gate electrodes as described in greater detail below. FIG. 7D illustrates a top-down view of a portion of the structure illustrated in FIGS. 7A, 7B, and 7C, including the second nanostructures 54A, along the reference cross-sections D-D′. FIG. 7E illustrates a top-down view of a portion of the structure illustrated in FIGS. 7A, 7B, and 7C, including the first nanostructures 52A, along the reference cross-sections E-E′. The conversion of the portions of the dummy gates 76 to the dielectric layers 77 may be done by reaction the portions of the dummy gates 76 with oxygen. In the embodiments wherein the dummy gates 76 comprise silicon, such as polycrystalline silicon, the dielectric layers 77 may comprise silicon oxide, such as silicon dioxide. In some embodiments, the dielectric layers 77 and the dummy gate dielectrics 71 comprise different materials. In some embodiments, the dielectric layers 77 and the dummy gate dielectrics 71 comprise a same material.

As shown in FIG. 7C, after the dielectric layers 77 are formed, the portions of the dummy gates 76 over the nanostructures 55 may have a width W₂ in a range from about 9 nm to about 14 nm, such as about 12.08 nm. The width W₂ may be smaller than the width W₁ as shown in FIG. 6C as a result of the conversion of the portions of the dummy gates 76 to the dielectric layers 77. The dielectric layers 77 may have a width W₃ in a range from about 0.8 nm to about 1.2 nm, such as about 1 nm. The dielectric layers 77 may be wider than the corresponding portions of the dummy gates 76 consumed for forming the dielectric layers 77. For example, a portion of the dummy gate 76 with a thickness of about 0.46 nm may be converted to the dielectric layer 77 with the thickness W₃. A total width of the dummy gate 76 with the corresponding dielectric layers 77 may be in a range from about 11 nm to about 16 nm, such as about 14.08 nm. As shown in FIGS. 7D and 7E, the dummy gate 76 has a similar shape as the dummy gate 76 described above with respect to FIGS. 6D and 6E, and portions of the dielectric layer 77 may have a shape of a bow with a convex inner sidewall in contact with the dummy gate 76 and a concave outer sidewall exposed.

In some embodiments, the conversion of the portions of the dummy gates 76 to the dielectric layers 77 are done by performing an annealing process, such as a rapid thermal annealing (RTA) process, with oxygen gas. The annealing temperature may be in a range from about 600° C. to about 800° C. The annealing time may be in a range from about 10 seconds to about 60 seconds. The annealing pressure may be in a range from about 1 torr to about 760 torr. The oxygen concentration in the annealing chamber may be in a range from about 500 ppm to about 1%.

In some embodiments, the conversion of the portions of the dummy gates 76 to the dielectric layers 77 are done by performing an annealing process, such as a RTA process, with oxygen gas and oxygen plasma. The annealing temperature may be in a range from about 200° C. to about 550° C. The annealing time may be in a range from about 10 seconds to about 60 seconds. The annealing pressure may be in a range from about 0.1 torr to about 5 torr. The oxygen flow rate may be in a range from about 100 sccm to about 1000 sccm. The oxygen plasma may be generated under a power in a range from about 2.5 kw to about 6 kw.

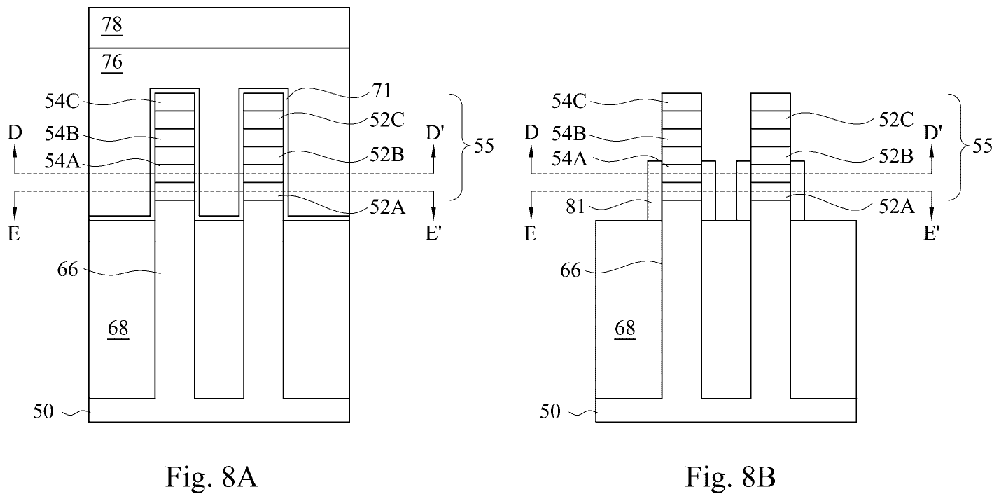

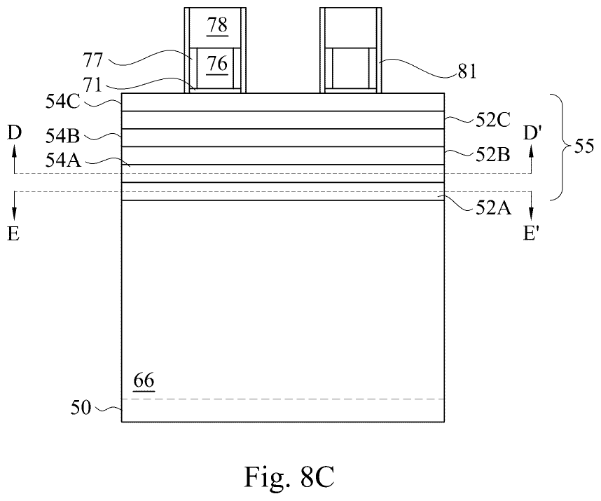

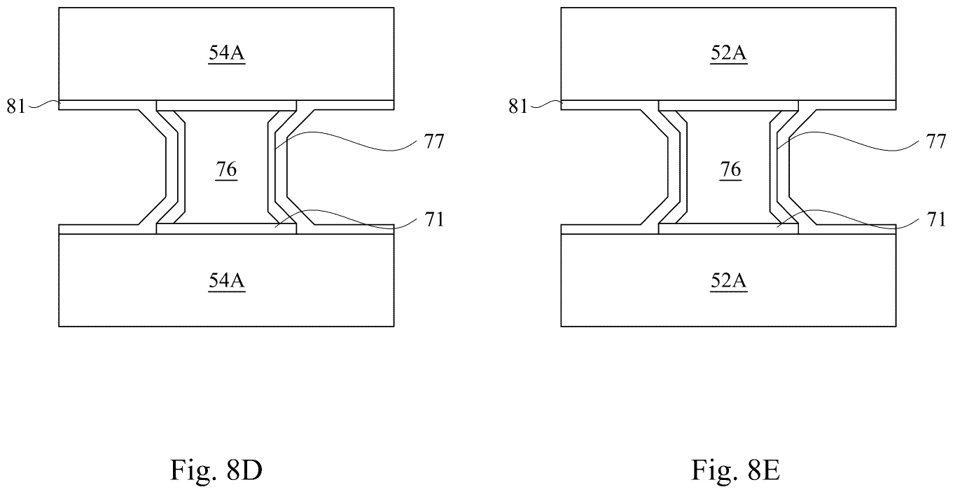

In FIGS. 8A through 8E, spacers 81 are formed on the sidewalls of the dielectric layers 77. FIG. 8D illustrates a top-down view of a portion of the structure illustrated in FIGS. 8A, 8B, and 8C, including the second nanostructures 54A, along the reference cross-sections D-D′. FIG. 8E illustrates a top-down view of a portion of the structure illustrated in FIGS. 8A, 8B, and 8C, including the first nanostructures 52A, along the reference cross-sections E-E′. The spacers 81 may protect the dummy gate dielectrics 71 and the dummy gate 76 during subsequent etching processes. The spacers 81 may be a single layer of one material or multiple sub-layers of different materials with different etch rates. In some embodiments, the spacers 81 comprise two sub-layers with different materials of different etch rates, which may be selected from silicon carbide, silicon nitride, silicon oxynitride, silicon oxycarbide, or the like. The materials of the dielectric layers 77 and the spacers 81 may be different.

The spacers 81 may be formed by forming a spacer layer by a suitable deposition process, such as CVD, ALD, or the like, and then patterning the spacer layer by a suitable etching process, such as an isotropic etching process (e.g., a wet etching process), an anisotropic etching process (e.g., a dry etching process), or the like. The spacer layer may be formed on top surfaces of the STI regions 68; top surfaces and sidewalls of the fins 66, the nanostructures 55, and the masks 78; and sidewalls of the dummy gates 76, the dummy gate dielectrics 71, and the dielectric layers 77. After the etching process, the spacers 81 may remain on sidewalls of the fins 66 and/or nanostructures 55 as illustrated in FIG. 8B; and sidewalls of the masks 78, the dummy gates 76, the dummy gate dielectrics 71, and the dielectric layers 77 as illustrated in FIGS. 8C through 8E.

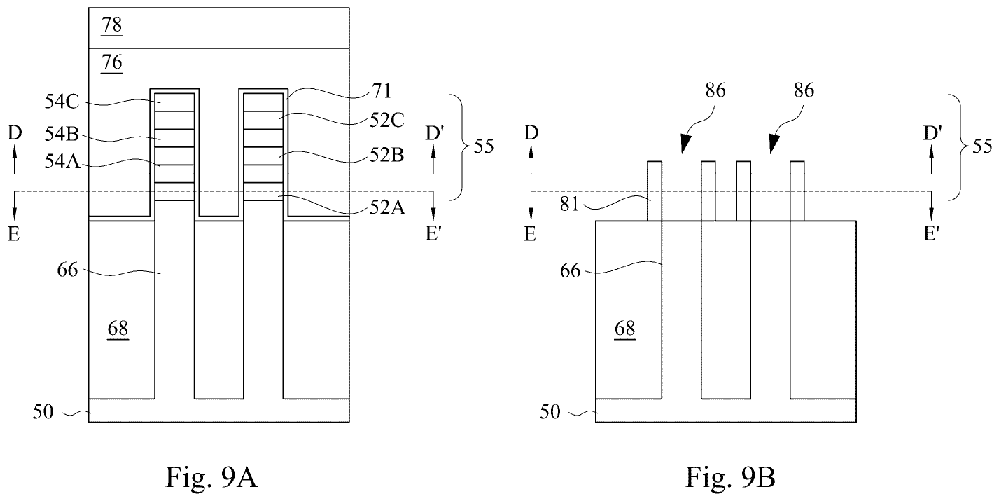

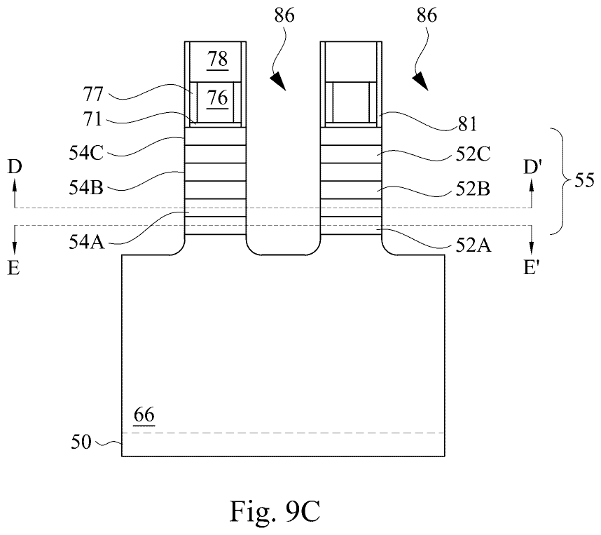

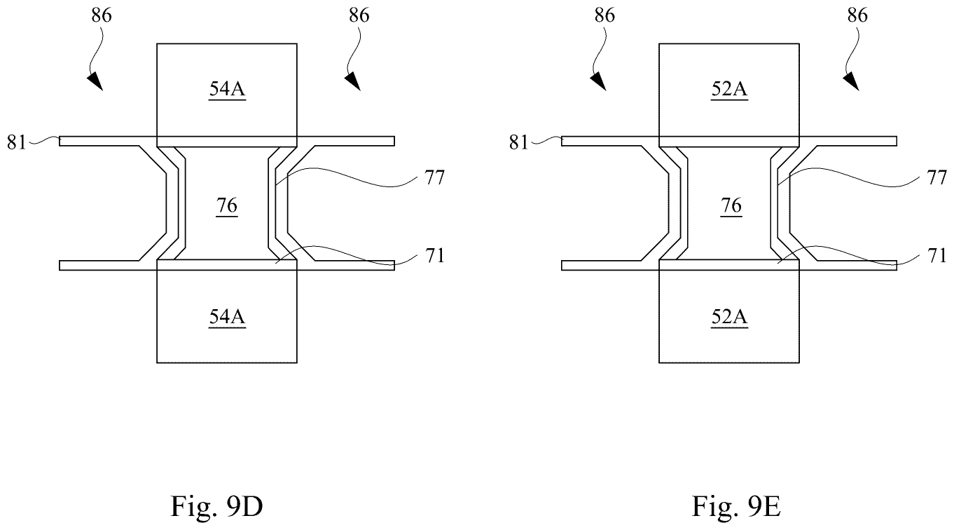

In FIGS. 9A through 9E, recesses 86 are formed in the fins 66, the nanostructures 55, and the substrate 50, in accordance with some embodiments. FIG. 9D illustrates a top-down view of a portion of the structure illustrated in FIGS. 9A, 9B, and 9C, including the second nanostructures 54A, along the reference cross-sections D-D′. FIG. 9E illustrates a top-down view of a portion of the structure illustrated in FIGS. 9A, 9B, and 9C, including the first nanostructures 52A, along the reference cross-sections E-E′. Epitaxial source/drain regions may be subsequently formed in the recesses 86. The recesses 86 may extend through the first nanostructures 52 and the second nanostructures 54, and into the substrate 50. As illustrated in FIG. 9B, top surfaces of the STI regions 68 may be level with bottom surfaces of the recesses 86. In some embodiments, the bottom surfaces of the recesses 86 are disposed below the top surfaces of the STI regions 68 or the like.

The recesses 86 may be formed by etching the fins 66, the nanostructures 55, and the substrate 50 using anisotropic etching processes, such as RIE, NBE, or the like. The spacers 81 and the masks 78 may mask portions of the fins 66, the nanostructures 55, and the substrate 50 during the etching processes used to form the recesses 86. A single etch process or multiple etch processes may be used to etch each layer of the nanostructures 55 and/or the fins 66. Timed etch processes may be used to stop the etching after the recesses 86 reach desired depths.

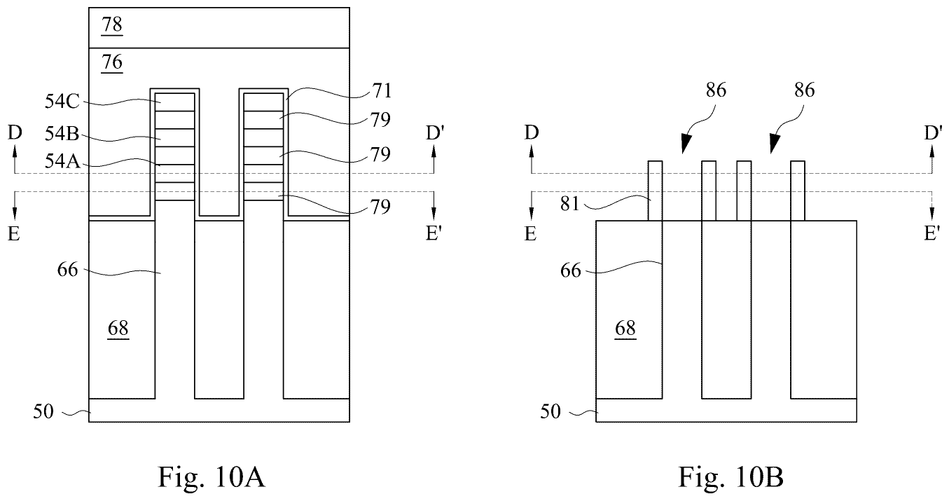

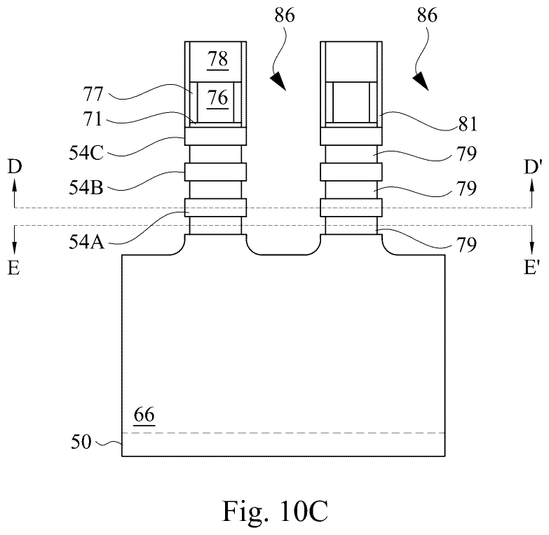

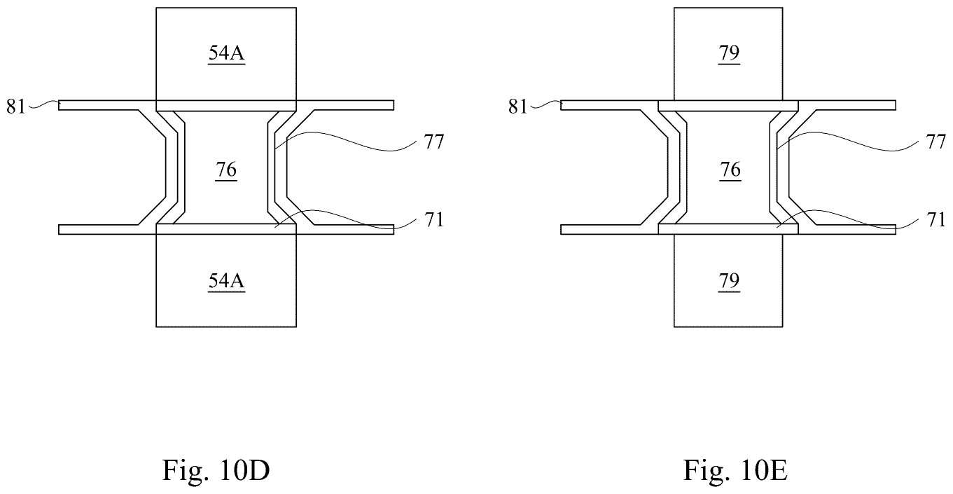

In FIGS. 10A through 10E, the first nanostructures 52 are replaced by sacrificial layers 79. FIG. 10D illustrates a top-down view of a portion of the structure illustrated in FIGS. 10A, 10B, and 10C, including the second nanostructures 54A, along the reference cross-sections D-D′. FIG. 10E illustrates a top-down view of a portion of the structure illustrated in FIGS. 10A, 10B, and 10C, including the sacrificial layers 79, along the reference cross-sections E-E′. Replacing the first nanostructures 52 with the sacrificial layers 79 may prevent defects from forming on surfaces of the second nanostructures 54 adjacent the first nanostructures 52 during subsequent annealing processes. Sidewalls of the sacrificial layers 79 may be recessed from sidewalls of the second nanostructures 54. The sidewalls of the sacrificial layers 79 are illustrated as being straight in FIG. 10C as an example, the sidewalls of the sacrificial layers 79 may be concave in some embodiments.

The sacrificial layers 79 may be formed by a suitable deposition process followed by a suitable etching process, which may remove excess portions of the deposited material. The deposition process may be CVD, ALD, or the like. The etching process may be a dry etching process using etchant(s), such as hydrofluoric acid, ammonia, and/or the like. The sacrificial layers 87 layer may comprise a dielectric material, such as silicon carbide, silicon nitride, silicon oxynitride, silicon oxycarbide, or the like. The materials of the dielectric layers 77 and the sacrificial layers 79 may be different.

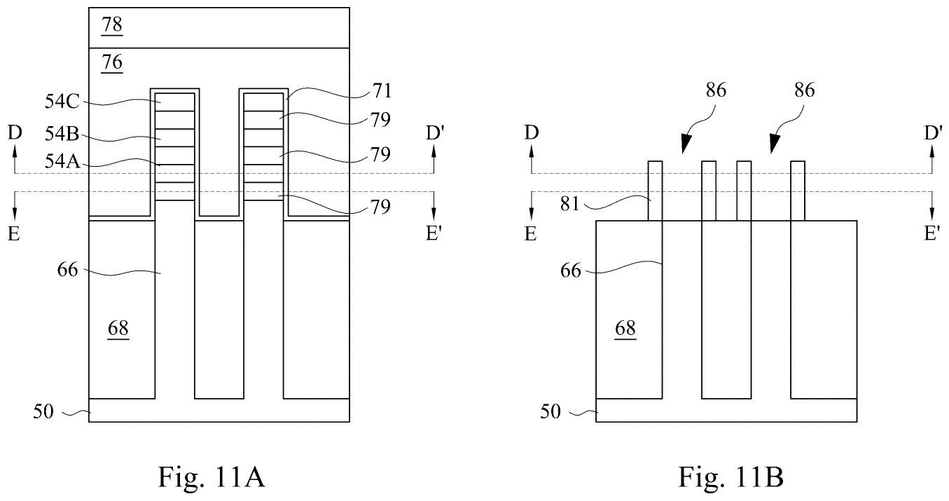

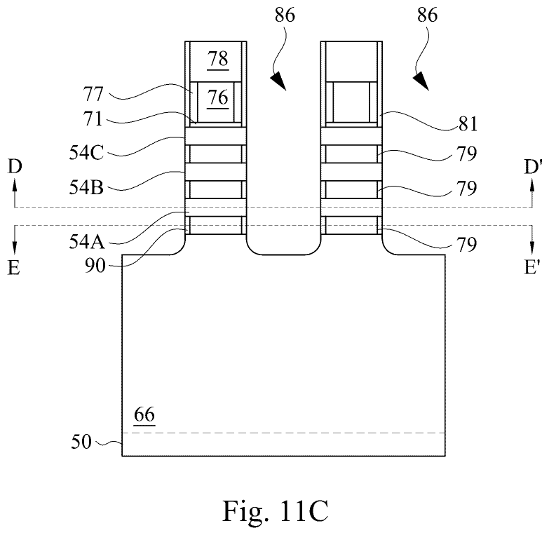

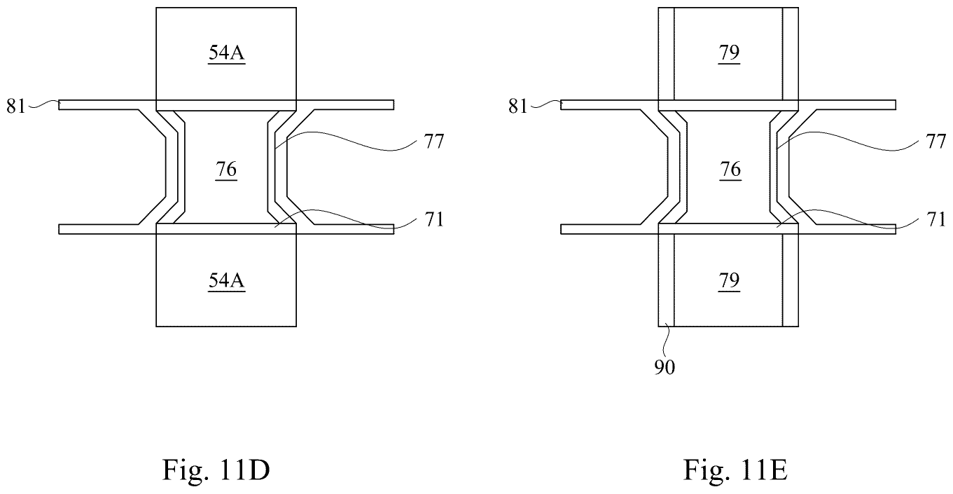

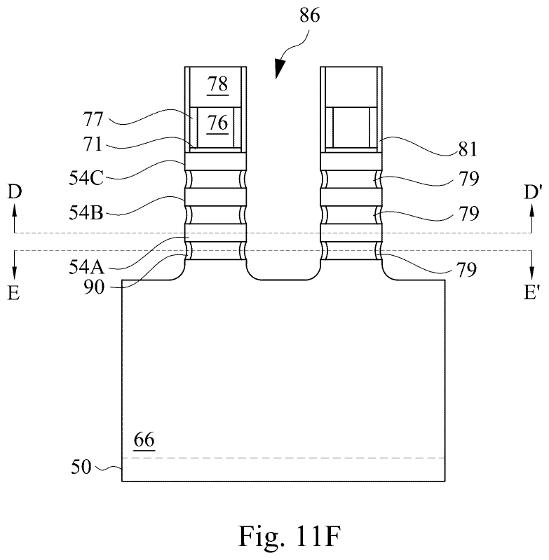

In FIGS. 11A through 11E, inner spacers 90 are formed on the sidewalls of the sacrificial layers 79. FIG. 11D illustrates a top-down view of a portion of the structure illustrated in FIGS. 11A, 11B, and 11C, including the second nanostructures 54A, along the reference cross-sections D-D′. FIG. 11E illustrates a top-down view of a portion of the structure illustrated in FIGS. 11A, 11B, and 11C, including the sacrificial layers 79, along the reference cross-sections E-E′. The inner spacers 90 may act as isolation features between subsequently formed source/drain regions and gate structures. As will be discussed in greater detail below, source/drain regions may be formed in the recesses 86, and the sacrificial layers 79 may be replaced with corresponding gate structures.

The inner spacers 90 may be formed by depositing an inner spacer layer (not separately illustrated) over the structures illustrated in FIGS. 10A through 10C, and then etching the inner spacer layer. The inner spacer layer may be deposited by a conformal deposition process, such as CVD, ALD, or the like. The inner spacer layer may comprise a material such as silicon nitride or silicon oxynitride, although any suitable material, such as low-dielectric constant (low-k) materials having a k-value less than about 3.5, may be utilized. The inner spacer layer may then be etched to form the inner spacers 90 by an anisotropic etching process, such as RIE, NBE, or the like. The inner spacers 90 may be used to protect subsequently formed source/drain regions during subsequent etching processes, such as etching processes used to form gate structures.

Outer sidewalls of the inner spacers 90 are illustrated as being flush with sidewalls of the second nanostructures 54 in FIG. 11C as an example, the outer sidewalls of the inner spacers 90 may extend beyond or be recessed from sidewalls of the second nanostructures 54. Moreover, the outer sidewalls of the inner spacers 90 are illustrated as being straight in FIG. 11C as an example, the outer sidewalls of the inner spacers 90 may be concave. FIG. 11F illustrates the embodiments in which sidewalls of the sacrificial layers 79 are concave, outer sidewalls of the inner spacers 90 are concave, and the inner spacers 90 are recessed from sidewalls of the second nanostructures 54.

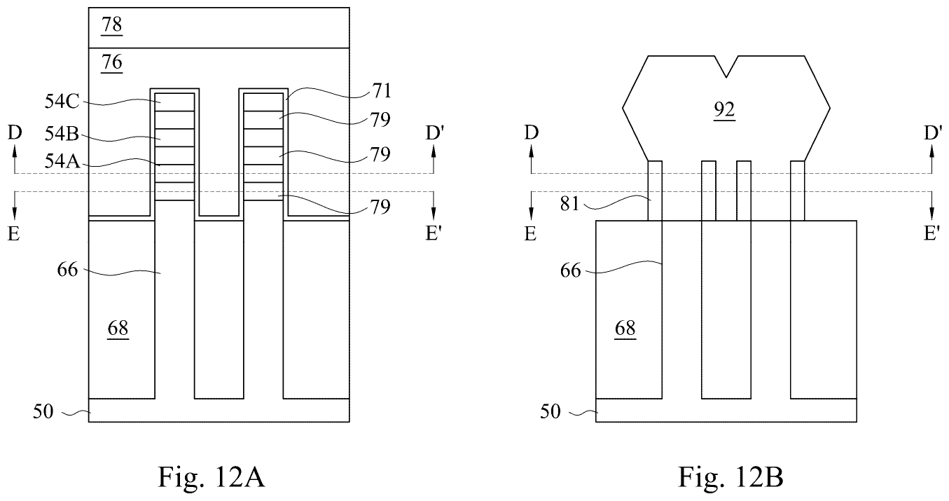

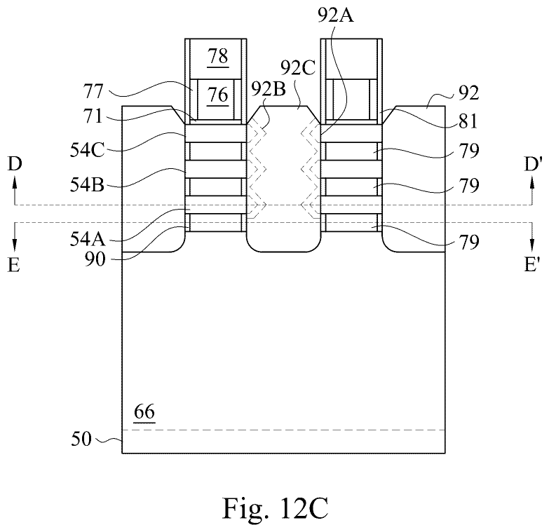

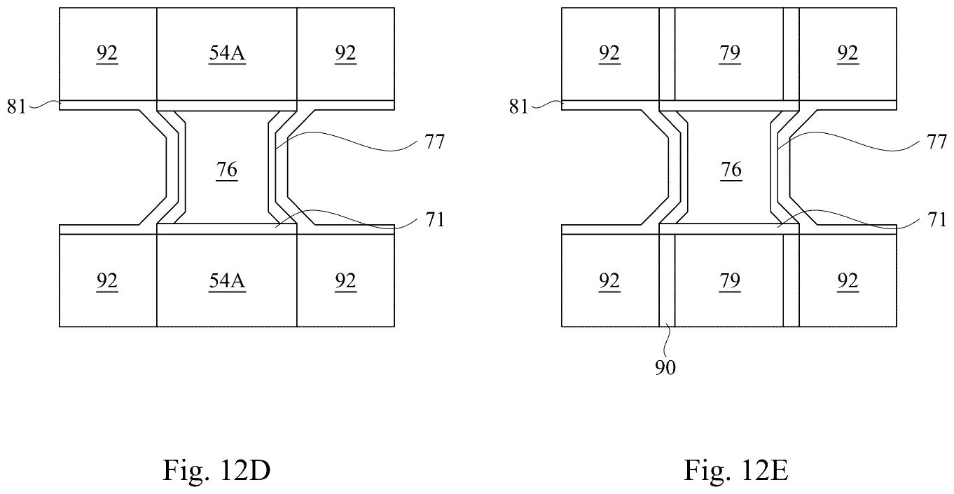

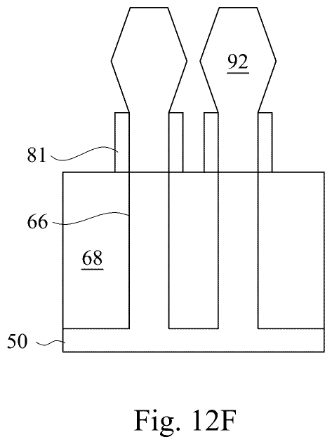

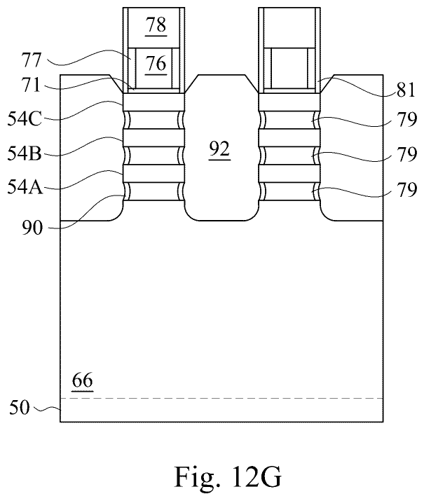

In FIGS. 12A through 12E, epitaxial source/drain regions 92 are formed in the recesses 86. FIG. 12D illustrates a top-down view of a portion of the structure illustrated in FIGS. 12A, 12B, and 12C, including the second nanostructures 54A, along the reference cross-sections D-D′. FIG. 12E illustrates a top-down view of a portion of the structure illustrated in FIGS. 12A, 12B, and 12C, including the sacrificial layers 79, along the reference cross-sections E-E′. In some embodiments, the epitaxial source/drain regions 92 may exert stress on the second nanostructures 54, thereby improving performance. As illustrated in FIG. 12C, the epitaxial source/drain regions 92 are formed in the recesses 86 such that each dummy gate 76 is disposed between respective neighboring pairs of the epitaxial source/drain regions 92. As illustrated in FIGS. 12D and 12E, the epitaxial source/drain regions 92 are separated from the dielectric layers 77 by the spacers 81.

The epitaxial source/drain regions 92 in the n-type region 50N, e.g., the NMOS region, may be formed by masking the p-type region 50P, e.g., the PMOS region. Then, the epitaxial source/drain regions 92 are epitaxially grown in the recesses 86 in the n-type region 50N. The epitaxial source/drain regions 92 may include any acceptable material appropriate for n-type nano-FETs. For example, if the second nanostructures 54 are silicon, the epitaxial source/drain regions 92 may include materials exerting a tensile strain on the second nanostructures 54, such as silicon, silicon carbide, phosphorous doped silicon carbide, silicon phosphide, or the like. The epitaxial source/drain regions 92 may have surfaces raised from respective upper surfaces of the nanostructures 55 and may have facets.

The epitaxial source/drain regions 92 in the p-type region 50P, e.g., the PMOS region, may be formed by masking the n-type region 50N, e.g., the NMOS region. Then, the epitaxial source/drain regions 92 are epitaxially grown in the recesses 86 in the p-type region 50P. The epitaxial source/drain regions 92 may include any acceptable material appropriate for p-type nano-FETs. For example, if the second nanostructures 54 are silicon, the epitaxial source/drain regions 92 may comprise materials exerting a compressive strain on the second nanostructures 54, such as silicon-germanium, boron doped silicon-germanium, germanium, germanium tin, or the like. The epitaxial source/drain regions 92 may also have surfaces raised from respective surfaces of the multi-layer stack 64 and may have facets.

The epitaxial source/drain regions 92, the second nanostructures 54, and/or the substrate 50 may be implanted with dopants to form source/drain regions, similar to the process previously discussed for forming lightly-doped source/drain regions, followed by an anneal. The source/drain regions may have an impurity concentration of between about 1×10¹⁹ atoms/cm³ and about 1×10²¹ atoms/cm³. The n-type and/or p-type impurities for source/drain regions may be any of the impurities previously discussed. In some embodiments, the epitaxial source/drain regions 92 may be in situ doped during growth.

As a result of the epitaxy processes used to form the epitaxial source/drain regions 92 in the n-type region 50N and the p-type region 50P, upper surfaces of the epitaxial source/drain regions 92 have facets which expand laterally outward beyond sidewalls of the nanostructures 55. In some embodiments, these facets cause adjacent epitaxial source/drain regions 92 of a same nano-FET to merge as illustrated by FIG. 12B. In some embodiments, adjacent epitaxial source/drain regions 92 remain separated after the epitaxy process is completed as illustrated by FIG. 12F. In the embodiments illustrated in FIGS. 12B and 12F, the spacers 81 may be formed to a top surface of the STI regions 68 thereby blocking the epitaxial growth. In some embodiments, the etching process used to form the spacers 81 may be adjusted to remove the spacer material to allow the epitaxially grown region to extend to the surface of the STI region 58.

The epitaxial source/drain regions 92 may comprise one or more semiconductor material layers. In some embodiments, the epitaxial source/drain regions 92 comprise first liner layers 92A on the sidewalls of the second nanostructures 54, second liner layers 92B on the first liner layers 92A, and fill layers 92C on the second liner layers 92B, as shown in FIG. 12C. The first liner layers 92A, the second liner layers 92B, and the fill layers 92C may be formed of different semiconductor materials and/or may be doped to different dopant concentrations. The first liner layers 92A may be grown first, the second liner layers 92B may be grown on the first liner layers 92A, and the fill layers 92C may be grown on the second liner layers 92B.

FIG. 12G illustrates the embodiments in which sidewalls of the sacrificial layers 79 are concave, outer sidewalls of the inner spacers 90 are concave, and the inner spacers 90 are recessed from sidewalls of the second nanostructures 54. As illustrated in FIG. 12G, the epitaxial source/drain regions 92 may be formed in contact with the inner spacers 90 and may extend past sidewalls of the second nanostructures 54.

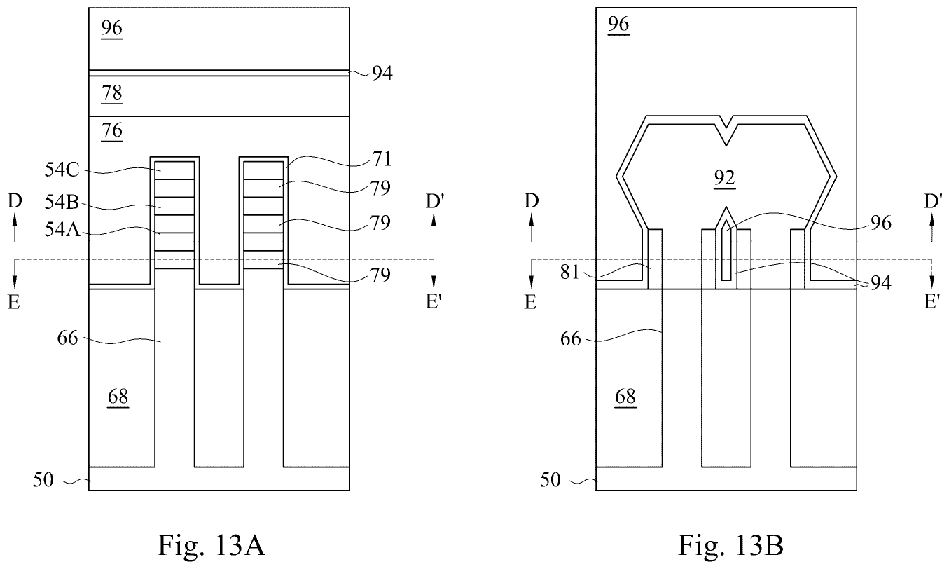

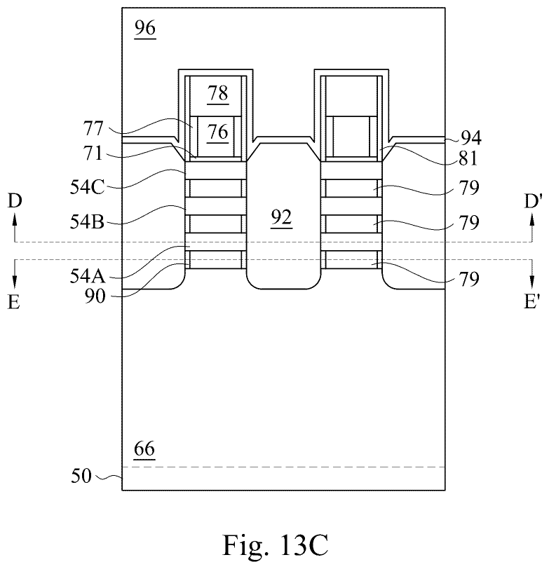

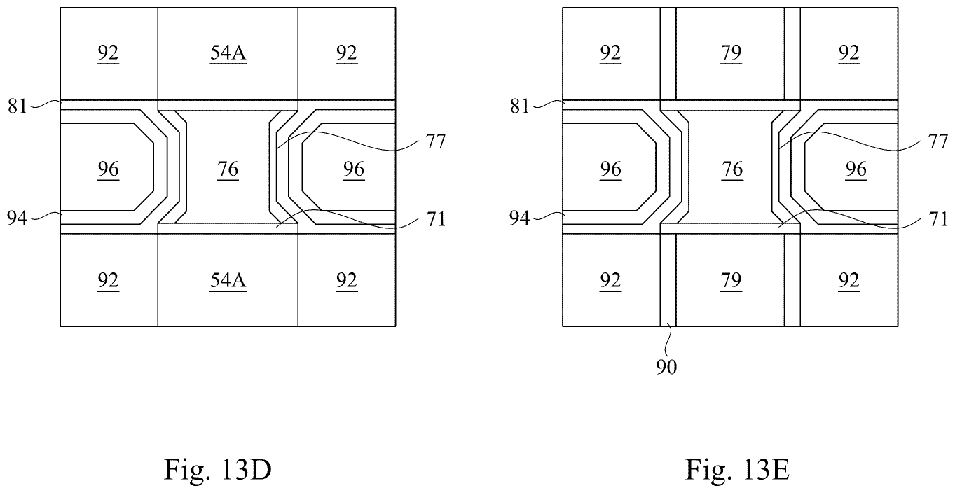

In FIGS. 13A through 13E, a first interlayer dielectric (ILD) 96 is deposited on the structure illustrated in FIGS. 12A through 12E. FIG. 13D illustrates a top-down view of a portion of the structure illustrated in FIGS. 13A, 13B, and 13C, including the second nanostructures 54A, along the reference cross-sections D-D′. FIG. 13E illustrates a top-down view of a portion of the structure illustrated in FIGS. 13A, 13B, and 13C, including the sacrificial layers 79, along the reference cross-sections E-E′.

The first ILD 96 may be formed of a dielectric material, and may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, a contact etch stop layer (CESL) 94 is disposed between the first ILD 96 and the epitaxial source/drain regions 92, the masks 78, and the spacers 81. The CESL 94 may comprise a dielectric material, such as, silicon nitride, silicon oxide, silicon oxynitride, or the like, having an etching selectivity to the material of the overlying first ILD 96.

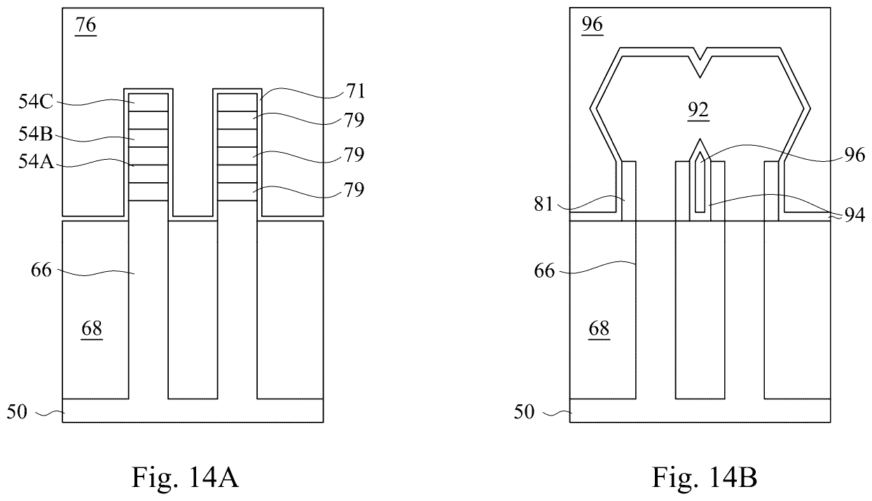

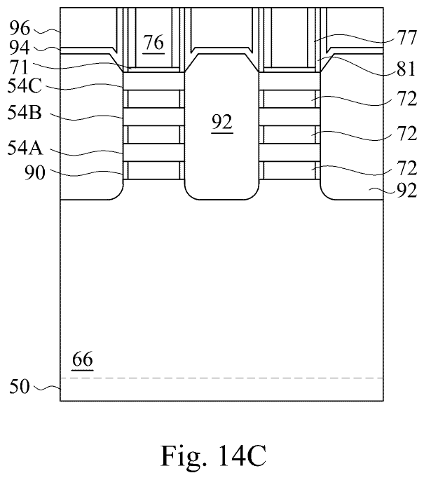

In FIGS. 14A through 14C, a planarization process, such as CMP or the like, may be performed to level the top surface of the first ILD 96 with the top surfaces of the dummy gates 76, the dielectric layers 77, and the spacers 81. The planarization process may also remove the masks 78 on the dummy gates 76, and portions of the spacers 81 along sidewalls of the masks 78. After the planarization process, top surfaces of the dummy gates 76, the dielectric layers 77, the spacers 81, and the first ILD 96 may be level within process variations. Accordingly, the top surfaces of the dummy gates 76 and the dielectric layers 77 are exposed. In some embodiments, portions of the masks 78 remain after the planarization process, in which case the planarization process levels the top surface of the first ILD 96 with top surface of the masks 78 and the spacers 81.

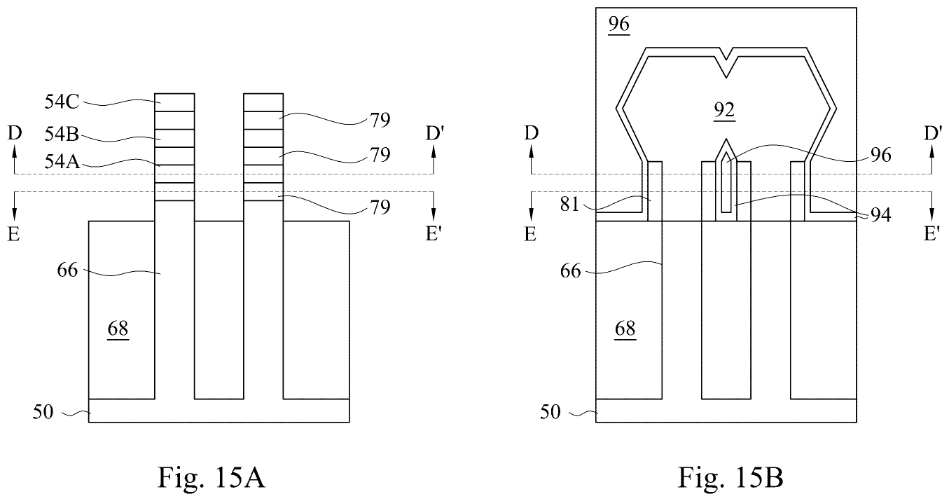

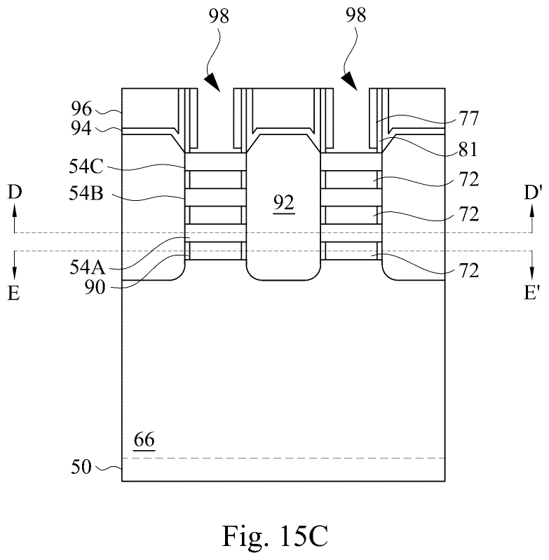

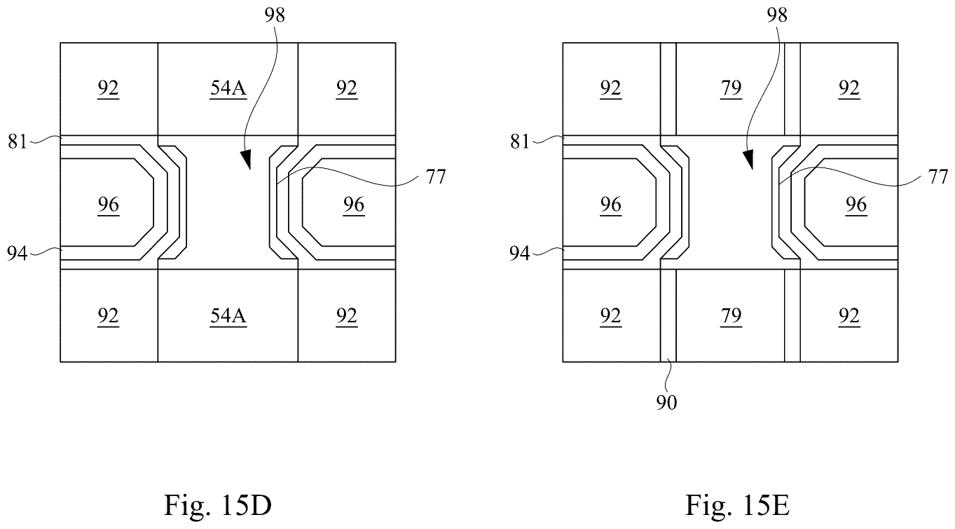

In FIGS. 15A through 15E, remaining portions of the dummy gates 76 and the dummy gate dielectrics 71 are removed in one or more etching processes to form third recesses 98. FIG. 15D illustrates a top-down view of a portion of the structure illustrated in FIGS. 15A, 15B, and 15C, including the second nanostructures 54A, along the reference cross-sections D-D′. FIG. 15E illustrates a top-down view of a portion of the structure illustrated in FIGS. 15A, 15B, and 15C, including the sacrificial layers 79, along the reference cross-sections E-E′. The dummy gates 76 and the dummy gate dielectrics 71 may be removed by an anisotropic dry etching process. The etching processes may use etchants that selectively etch the dummy gates 76 and the dummy gate dielectrics 71 while the first ILD 96, the inner spacers 90, and the spacers 81 may be substantially intact. In the embodiments wherein the dielectric layers 77 and the dummy gate dielectrics 71 comprise different materials, the dielectric layers 77 are substantially intact after the etching processes. In the embodiments wherein the dielectric layers 77 and the dummy gate dielectrics 71 comprise a same material, the dielectric layers 77 are partially removed and have remaining portions with a reduced thickness after the etching processes. During the etching processes, the dummy gate dielectrics 71 may be used as etch stop layers when the dummy gates 76 are removed and may be removed after the removal of the dummy gates 76. After the etching processes, the second nanostructures 54, the sacrificial layers 79, the inner spacers 90, and the dielectric layers 77 may be exposed.

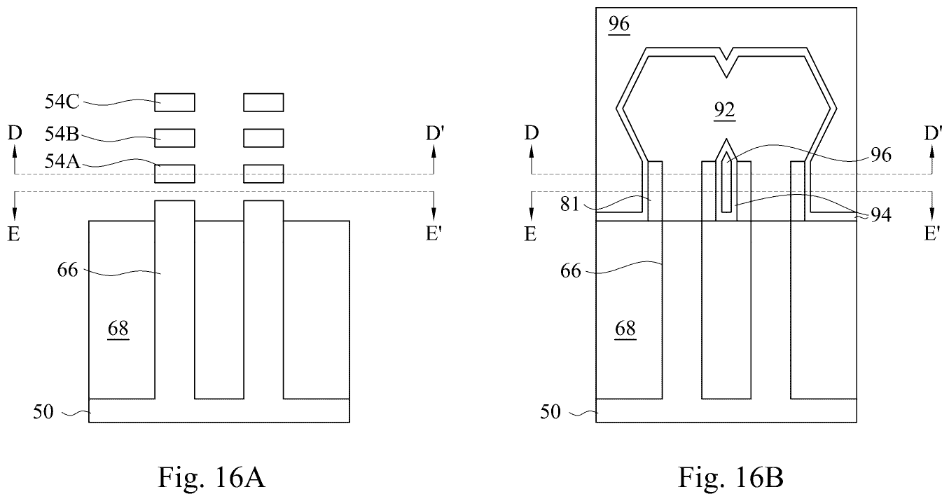

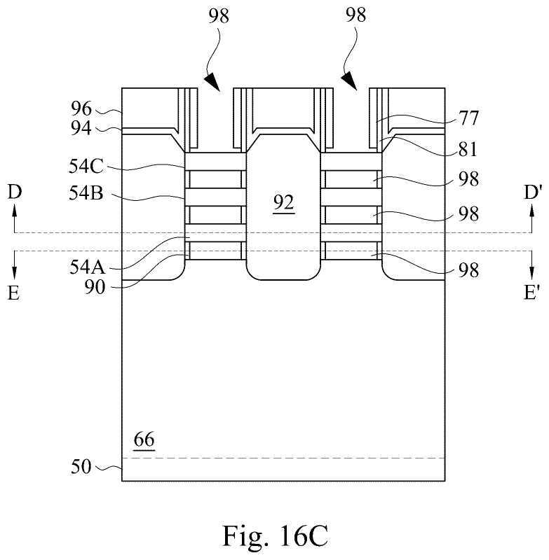

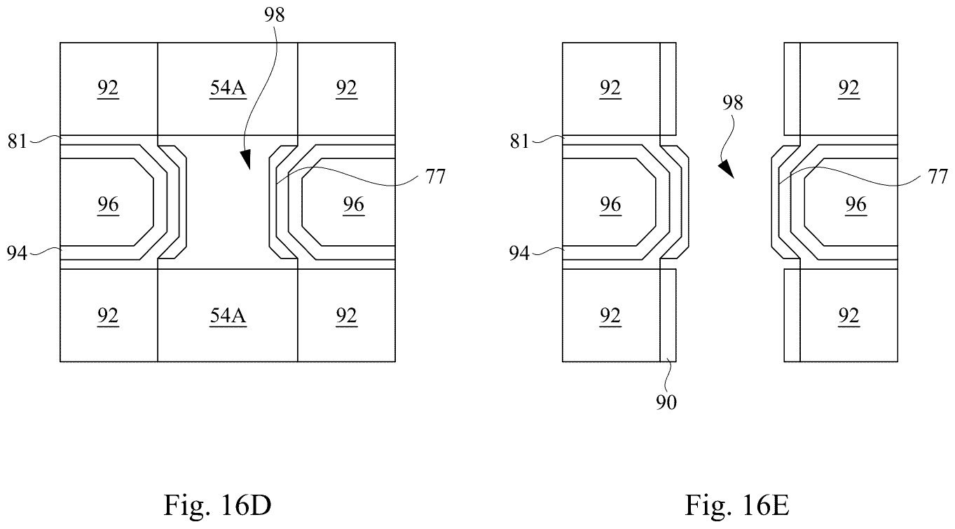

In FIGS. 16A through 16E, the sacrificial layers 79 are removed, which extends the third recesses 98. FIG. 16D illustrates a top-down view of a portion of the structure illustrated in FIGS. 16A, 16B, and 16C, including the second nanostructures 54A, along the reference cross-sections D-D′. FIG. 16E illustrates a top-down view of a portion of the structure illustrated in FIGS. 16A, 16B, and 16C along the reference cross-sections E-E′. The sacrificial layers 79 may be removed using one or more suitable etching processes, such as an isotropic etching process. The etching processes may be wet or drying etching processes using fluorine based chemicals as etchants. During the etching processes the sacrificial layers 79 may be selectively etched while the second nanostructures 54, the dielectric layers 77, the spacers 81, the inner spacers 90, and the epitaxial source/drain regions 92 may be substantially intact.

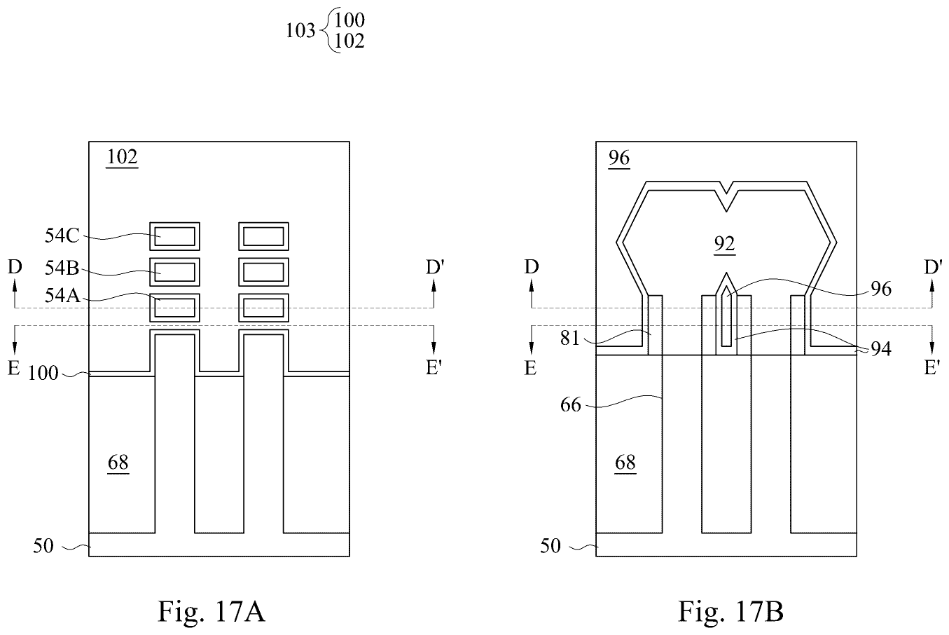

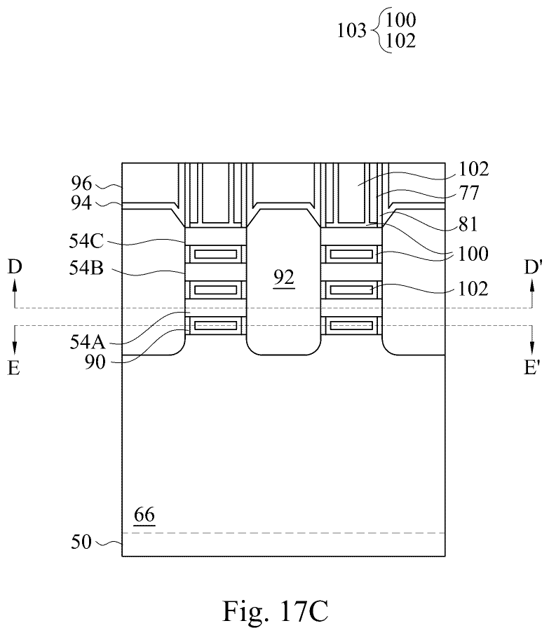

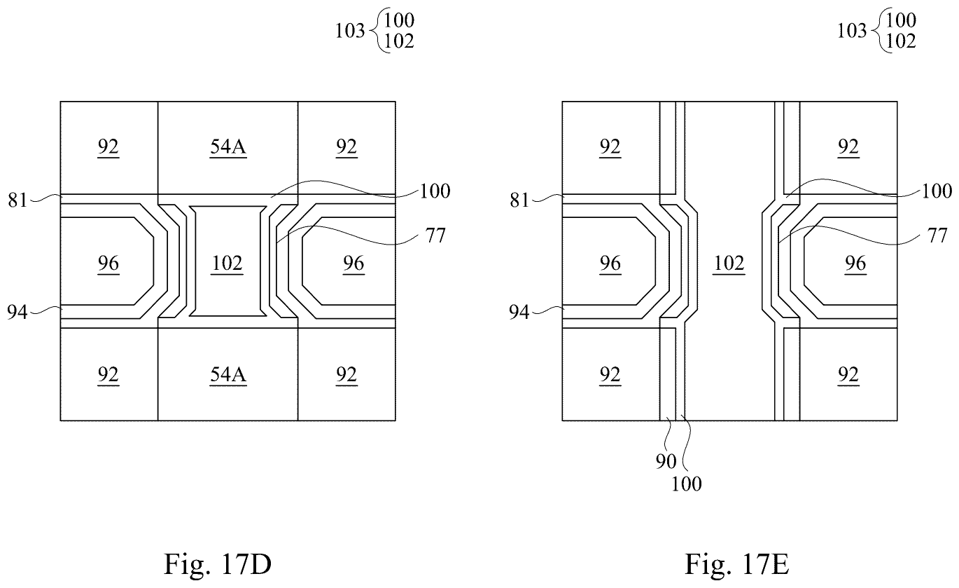

In FIGS. 17A through 17E, gate dielectrics 100 and gate electrodes 102 are formed in the third recesses 98. FIG. 17D illustrates a top-down view of a portion of the structure illustrated in FIGS. 17A, 17B, and 17C, including the second nanostructures 54A, along the reference cross-sections D-D′. FIG. 17E illustrates a top-down view of a portion of the structure illustrated in FIGS. 17A, 17B, and 17C along the reference cross-sections E-E′. The dielectric layers 77 may be between the gate dielectrics 100 and the spacers 81. Due to the dielectric layers 77, the gate electrodes 102 may be disposed further away from the epitaxial source/drain regions 92 and increased electrical insulation may be achieved between the gate electrodes 102 and the epitaxial source/drain regions 92. As a result, a risk of electrical leakage and parasitic capacitance between the epitaxial source/drain regions 92 and the gate electrodes 102 may be decreased, thereby improving the performance and reliability of the subsequently formed semiconductor device.

The gate dielectrics 100 may be deposited conformally in the third recesses 98. The gate dielectrics 100 may be formed on top surfaces and sidewalls of the substrate 50 and on top surfaces, sidewalls, and bottom surfaces of the second nanostructures 54. The gate dielectrics 100 may be deposited on top surfaces of the first ILD 96, the CESL 94, the spacers 81, and the STI regions 68, bottom surfaces of the dielectric layers 77, as well as on sidewalls of the spacers 81, the dielectric layers 77, and the inner spacers 90. As illustrated in FIGS. 17D and 17E, the gate dielectric 100 may be in contact with the convex inner sidewalls of the dielectric layer 77 and the second nanostructures 54A are separated from the dielectric layers 77 by the gate dielectric 100. The gate dielectrics 100 comprise one or more dielectric layers. In some embodiments, the gate dielectrics 100 include a high-k dielectric material, such as an oxide or a silicate of hafnium, aluminum, zirconium, lanthanum, manganese, barium, titanium, lead, or combinations thereof. The materials of the dielectric layers 77 and gate dielectrics 100 may be different. The gate dielectrics 100 may be formed by a suitable deposition method, such as molecular-beam deposition (MBD), ALD, PECVD, or the like.

The gate electrodes 102 may be formed on the gate dielectrics 100 and fill the remaining portions of the third recesses 98 by plating or the like. As shown in FIG. 17D, the gate electrode 102 may have concave sidewalls. A width of a portion of the gate electrode 102 between the neighboring second nanostructures 54A may decrease as the gate electrode 102 extends away from the second nanostructures 54A. The gate electrodes 102 may include a metal-containing material, such as titanium nitride, titanium oxide, tantalum nitride, tantalum carbide, cobalt, ruthenium, aluminum, tungsten, or combinations thereof. Single layer gate electrodes 102 are illustrated in FIGS. 17A, 17C, 17D, and 17E as an example, the gate electrodes 102 may comprise any number of liner layers, any number of work function tuning layers, and a fill material. After the filling of the third recesses 98, a planarization process, such as CMP, may be performed to remove the excess portions of the gate dielectrics 100 and the material of the gate electrodes 102, which excess portions are over the top surface of the first ILD 96. The gate electrodes 102 and the gate dielectrics 100 may be collectively referred to as gate structures 103.

The formation of the gate dielectrics 100 in the n-type region 50N and the p-type region 50P may occur simultaneously such that the gate dielectrics 100 in each region are formed from the same materials, and the formation of the gate electrodes 102 may occur simultaneously such that the gate electrodes 102 in each region are formed from the same materials. In some embodiments, the gate dielectrics 100 in each region may be formed by distinct processes, such that the gate dielectrics 100 may be different materials and/or have a different number of layers, and/or the gate electrodes 102 in each region may be formed by distinct processes, such that the gate electrodes 102 may be different materials and/or have a different number of layers. Various masking steps may be used to mask and expose appropriate regions when using distinct processes.

FIGS. 17F and 17G show structure similar to the one shown in FIG. 17D in accordance with some embodiments, wherein like numerals refer to like features formed by like processes. In the embodiments shown in FIGS. 17F and 17G, interfacial layers 101 are formed on the exposed surfaces of the second nanostructures 54 before the gate dielectrics 100 are deposited. The interfacial layers 101 may be between and in contact with the gate dielectrics 100 and the second nanostructures 54. The interfacial layers 101 may be in contact with the spacers 81. The interfacial layers 101 may comprise a dielectric material, such as silicon oxide, or the like. In some embodiments, the interfacial layers 101 and the dielectric layers 77 comprise a same material. The interfacial layers 101 may be formed by a suitable oxidation method, such as thermal oxidation, chemical oxidation, or the like. In some embodiments, the interfacial layers 101 and the dielectric layers 77 are formed of different processes. In the embodiments shown in FIG. 17F, the interfacial layers 101 are separated from the dielectric layers 77 by the gate dielectrics 100. In the embodiments shown in FIG. 17G, the interfacial layers 101 are in contact with the dielectric layers 77.

FIGS. 3 through 17E illustrate embodiments where the first nanostructures 52 are replaced by the sacrificial layers 79 initially, and then the sacrificial layers 79 are removed to make space for the gate structures 103. In other embodiments, the first nanostructures 52 are not replaced by the sacrificial layers 79 and the first nanostructures 52 are removed to make space for the gate structures 103 directly.

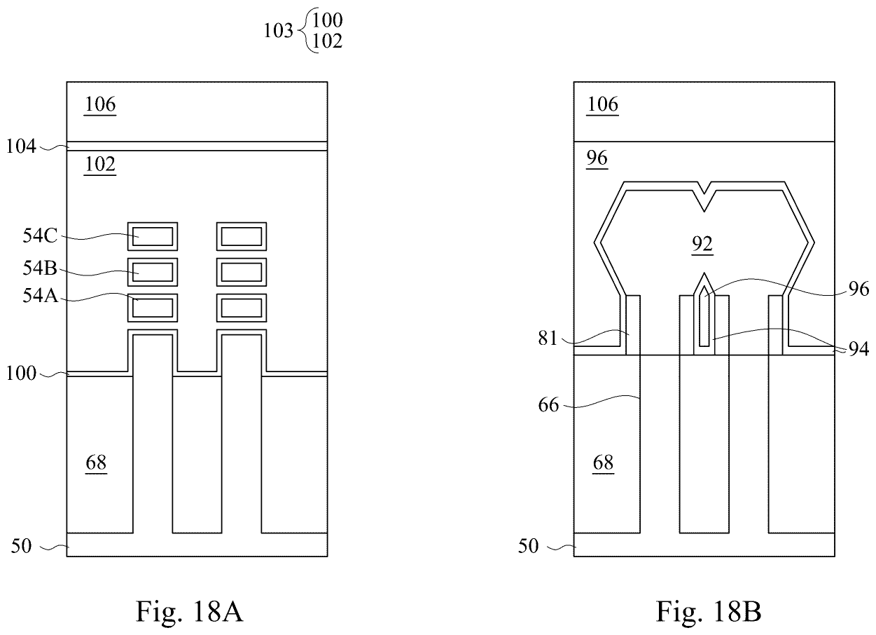

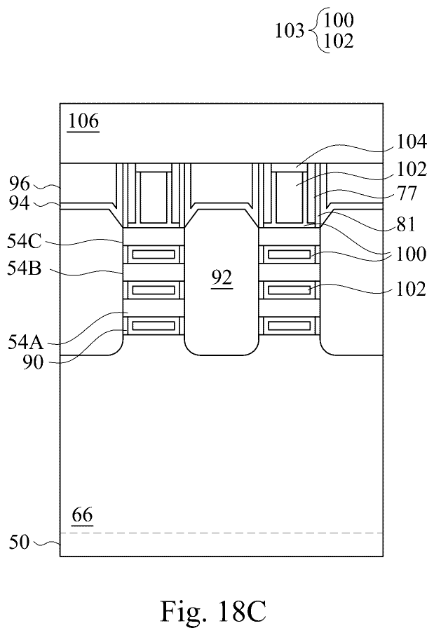

In FIGS. 18A through 18C, the gate structures 103 are recessed, and recesses are formed directly over the gate structures 103 and between opposing portions of spacers 81. Gate masks 104 comprising one or more layers of dielectric material, such as silicon nitride, silicon oxynitride, or the like, are filled in the recesses, followed by a planarization process to remove excess portions of the dielectric material extending over the first ILD 96. Subsequently formed gate contacts may extend through the gate masks 104 to contact the top surfaces of the recessed gate electrodes 102. As further illustrated by FIGS. 18A through 18C, a second ILD 106 is deposited over the first ILD 96 and over the gate masks 104. In some embodiments, the second ILD 106 is a flowable film formed by FCVD. In some embodiments, the second ILD 106 is formed of a dielectric material such as PSG, BSG, BPSG, USG, or the like, and may be deposited by any suitable method, such as CVD, PECVD, or the like. In some embodiments, the gate masks 104 may be omitted and the second ILD 106 is formed on the gate structures 103 and the first ILD 96.

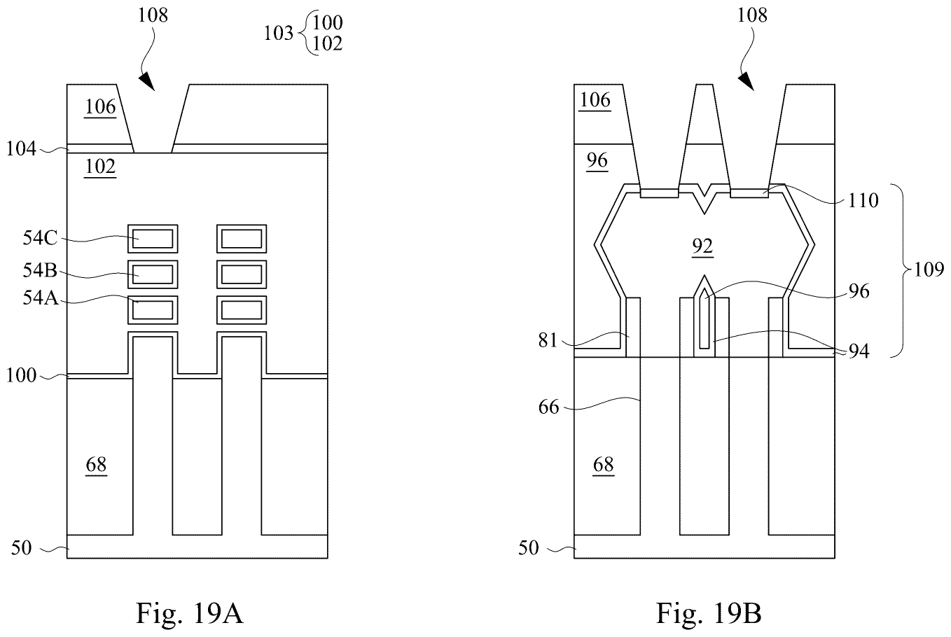

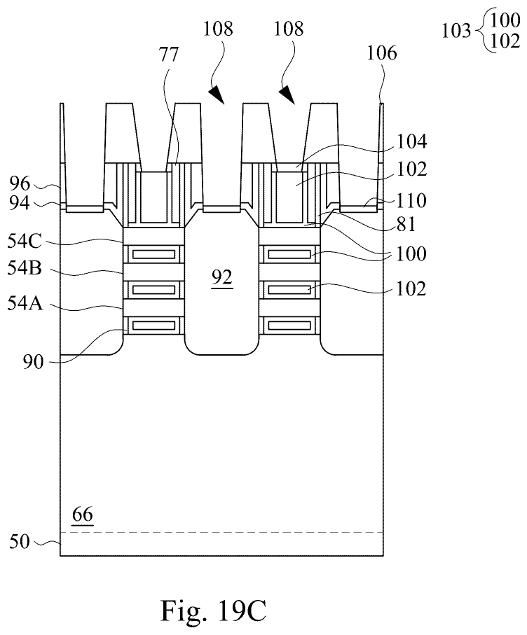

In FIGS. 19A through 19C, the second ILD 106, the first ILD 96, the CESL 94, and the gate masks 104 are etched to form fourth recesses 108 exposing surfaces of the epitaxial source/drain regions 92 and/or some of the gate structures 103. The fourth recesses 108 may be formed by etching using an anisotropic etching process, such as RIE, NBE, or the like. In some embodiments, the fourth recesses 108 may be etched through the second ILD 106 and the first ILD 96 using a first etching process; may be etched through the gate masks 104 using a second etching process; and may then be etched through the CESL 94 using a third etching process. A mask, such as a photoresist, may be formed and patterned over the second ILD 106 to mask portions of the second ILD 106 from the first etching process and the second etching process. In some embodiments, the fourth recesses 108 extend into the epitaxial source/drain regions 92 and/or some of the gate structures, and a bottom of the fourth recesses 108 may be level with (e.g., at a same level, or having a same distance from the substrate 50), or lower than (e.g., closer to the substrate 50) the epitaxial source/drain regions 92 and/or some of the gate structures.

After the fourth recesses 108 are formed, first silicide regions 110 are formed over the epitaxial source/drain regions 92. In some embodiments, the first silicide regions 110 are formed by first depositing a metal (not separately illustrated) capable of reacting with the semiconductor materials of the underlying epitaxial source/drain regions 92 (e.g., silicon, silicon germanium, germanium) to form silicide or germanide regions, such as nickel, cobalt, titanium, tantalum, platinum, tungsten, other noble metals, other refractory metals, rare earth metals or their alloys, over the exposed portions of the epitaxial source/drain regions 92, then performing a first thermal annealing process to form the first silicide regions 110. The un-reacted portions of the deposited metal are then removed, e.g., by an etching process. Although the first silicide regions 110 are referred to as silicide regions, the first silicide regions 110 may also be germanide regions, or silicon germanide regions (e.g., regions comprising silicide and germanide).

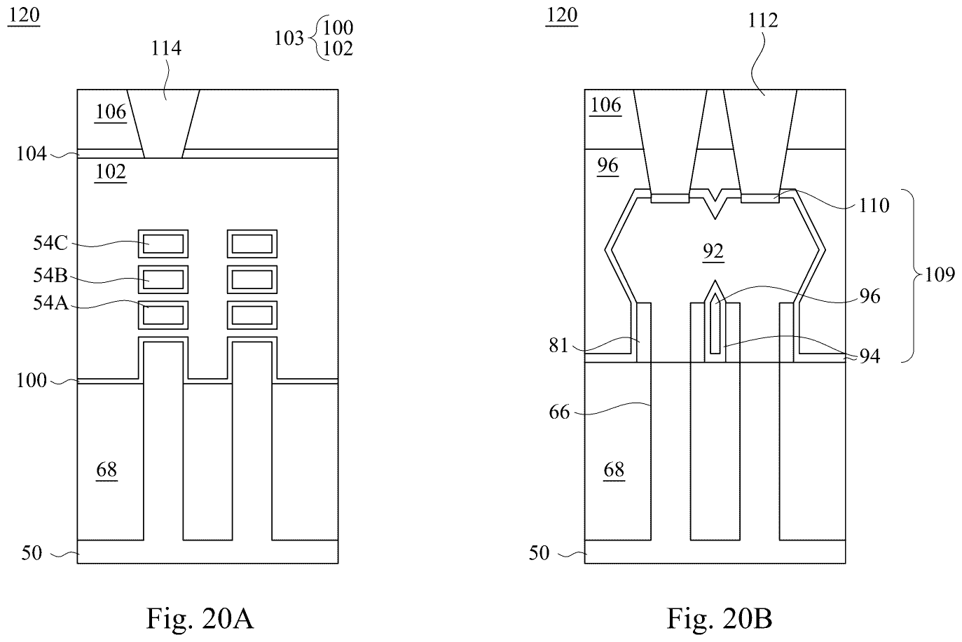

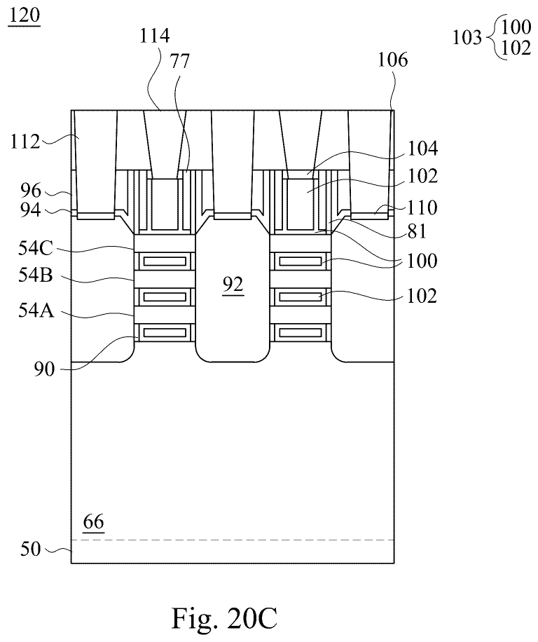

In FIGS. 20A through 20C, source/drain contacts 112 and gate contacts 114, which may be also referred to as conductive contacts, are formed in the fourth recesses 108. The structure shown in FIGS. 20A through 20C may be referred to as semiconductor device 120. The source/drain contacts 112 and the gate contacts 114 may each comprise one or more layers, such as barrier layers, diffusion layers, and fill materials. In some embodiments, the source/drain contacts 112 and the gate contacts 114 each include a barrier layer and a conductive material, and are each electrically connected to an underlying conductive feature (e.g., a gate electrode 102 and/or a first silicide region 110). The gate contacts 114 are electrically connected to the gate electrodes 102 and the source/drain contacts 112 are electrically connected to the first silicide regions 110. The barrier layer may include titanium, titanium nitride, tantalum, tantalum nitride, or the like. The conductive material may be copper, a copper alloy, silver, gold, tungsten, cobalt, aluminum, nickel, or the like. A planarization process, such as CMP, may be performed to remove excess material from surfaces of the second ILD 106.

The embodiments of the present disclosure have some advantageous features. By forming the dielectric layers 77, the gate electrodes 102 may be disposed further away from the epitaxial source/drain regions 92 and increased electrical insulation may exist between the gate electrodes 102 and the epitaxial source/drain regions 92. As a result, the risk of electrical leakage and parasitic capacitance between the epitaxial source/drain regions 92 and the gate electrodes 102 may be decreased, thereby improving the performance and reliability of the semiconductor device 120.

In an embodiment, a semiconductor device includes a first source/drain region; a first nanostructure adjacent the first source/drain region; a second source/drain region; a second nanostructure adjacent the second source/drain region; a gate structure around the first nanostructure and the second nanostructure, wherein the gate structure includes a gate electrode and a gate dielectric, and wherein a first portion of the gate electrode and a first portion of the gate dielectric are between the first nanostructure and the second nanostructure; a spacer, wherein a first portion of the spacer is between the first source/drain region and the second source/drain region; and a dielectric layer, wherein a first portion of the dielectric layer is between the first portion of the gate dielectric and the first portion of the spacer, and wherein the dielectric layer includes a different material from the gate dielectric and the spacer. In an embodiment, the dielectric layer includes silicon oxide. In an embodiment, the first portion of the dielectric layer is separated from the first nanostructure and the second nanostructure by the first portion of the gate dielectric. In an embodiment, the first portion of the dielectric layer is separated from the first source/drain region and the second source/drain region by the first portion of the spacer. In an embodiment, the first portion of the dielectric layer has a convex sidewall in contact with the first portion of the gate dielectric and a concave sidewall in contact with the first portion of the spacer in a top-down view. In an embodiment, a width of the first portion of the gate electrode decreases as the first portion of the gate electrode extends away from the first nanostructure and the second nanostructure in a top-down view. In an embodiment, a second portion of the dielectric layer, a second portion of the gate dielectric, and a second portion of the spacer are over the first nanostructure and the second nanostructure, and wherein the second portion of the dielectric layer is between the second portion of the gate dielectric and the second portion of the spacer.

In an embodiment, a semiconductor device includes a first nanostructure; a gate structure around the first nanostructure, wherein the gate structure includes a gate electrode and a gate dielectric, and wherein a first portion of the gate electrode and a first portion of the gate dielectric are over the first nanostructure; a spacer, wherein a first portion of the spacer is over the first nanostructure; a first source/drain region in contact with the first nanostructure; and a dielectric layer, wherein a first portion of the dielectric layer is over the first nanostructure and the first portion of the gate dielectric, wherein the first portion of the dielectric layer is between the first portion of the gate dielectric and the first portion of the spacer, and wherein the dielectric layer includes a different material from the gate dielectric and the spacer. In an embodiment, the first portion of the gate dielectric is between the first portion of the dielectric layer and the first nanostructure. In an embodiment, a bottom surface of the first portion of the dielectric layer is in contact with the first portion of the gate dielectric. In an embodiment, the first portion of the spacer is between the first portion of the dielectric layer and the first source/drain region. In an embodiment, a second portion of the gate dielectric is in contact with the first nanostructure, wherein a second portion of the spacer is in contact with the second portion of the gate dielectric, and wherein a second portion of the dielectric layer is between the second portion of the gate dielectric and the second portion of the spacer in a top-down view. In an embodiment, the dielectric layer includes silicon oxide.

In an embodiment, a method of forming a semiconductor device includes forming a first nanostructure over a substrate; forming a dummy gate structure over the substrate, wherein the dummy gate structure include a dummy gate and a dummy gate dielectric, and wherein the dummy gate dielectric is in contact with the first nanostructure; converting a first portion of the dummy gate at a sidewall of the dummy gate to a dielectric layer; removing a remaining portion of the dummy gate structure to form a first opening; and forming a gate structure in the first opening, wherein the gate structure includes a gate electrode and a gate dielectric, and wherein the gate dielectric is in contact with the first nanostructure and the dielectric layer. In an embodiment, converting the first portion of the dummy gate at the sidewall of the dummy gate to the dielectric layer includes performing an annealing process with oxygen gas. In an embodiment, the annealing process is performed further with oxygen plasma. In an embodiment, the dielectric layer and the gate dielectric include different materials. In an embodiment, the dummy gate includes polycrystalline silicon and the dielectric layer includes silicon oxide. In an embodiment, a first portion of the gate dielectric is in contact with the first nanostructure, wherein a first portion of the dielectric layer is in contact with the first portion of the gate dielectric, and wherein the first portion of the dielectric layer has a shape of a bow in a top-down view. In an embodiment, the first portion of the dielectric layer is separated from the first nanostructure by the first portion of the gate dielectric.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
a first source/drain region;
a first nanostructure adjacent the first source/drain region;
a second source/drain region;
a second nanostructure adjacent the second source/drain region;
a gate structure around the first nanostructure and the second nanostructure, wherein the gate structure comprises a gate electrode and a gate dielectric, and wherein a first portion of the gate electrode and a first portion of the gate dielectric are between the first nanostructure and the second nanostructure;
a spacer, wherein a first portion of the spacer is between the first source/drain region and the second source/drain region; and
a dielectric layer, wherein a first portion of the dielectric layer is between the first portion of the gate dielectric and the first portion of the spacer, and wherein the dielectric layer comprises a different material from the gate dielectric and the spacer.

2. The semiconductor device of claim 1, wherein the dielectric layer comprises silicon oxide.

3. The semiconductor device of claim 1, wherein the first portion of the dielectric layer is separated from the first nanostructure and the second nanostructure by the first portion of the gate dielectric.

4. The semiconductor device of claim 1, wherein the first portion of the dielectric layer is separated from the first source/drain region and the second source/drain region by the first portion of the spacer.

5. The semiconductor device of claim 1, wherein the first portion of the dielectric layer has a convex sidewall in contact with the first portion of the gate dielectric and a concave sidewall in contact with the first portion of the spacer in a top-down view.

6. The semiconductor device of claim 1, wherein a width of the first portion of the gate electrode decreases as the first portion of the gate electrode extends away from the first nanostructure and the second nanostructure in a top-down view.

7. The semiconductor device of claim 1, wherein a second portion of the dielectric layer, a second portion of the gate dielectric, and a second portion of the spacer are over the first nanostructure and the second nanostructure, and wherein the second portion of the dielectric layer is between the second portion of the gate dielectric and the second portion of the spacer.

8. A semiconductor device comprising:
a first nanostructure;
a gate structure around the first nanostructure, wherein the gate structure comprises a gate electrode and a gate dielectric, and wherein a first portion of the gate electrode and a first portion of the gate dielectric are over the first nanostructure;
a spacer, wherein a first portion of the spacer is over the first nanostructure;
a first source/drain region in contact with the first nanostructure; and
a dielectric layer, wherein a first portion of the dielectric layer is over the first nanostructure and the first portion of the gate dielectric, wherein the first portion of the dielectric layer is between the first portion of the gate dielectric and the first portion of the spacer, and wherein the dielectric layer comprises a different material from the gate dielectric and the spacer.

9. The semiconductor device of claim 8, wherein the first portion of the gate dielectric is between the first portion of the dielectric layer and the first nanostructure.

10. The semiconductor device of claim 9, wherein a bottom surface of the first portion of the dielectric layer is in contact with the first portion of the gate dielectric.

11. The semiconductor device of claim 8, wherein the first portion of the spacer is between the first portion of the dielectric layer and the first source/drain region.

12. The semiconductor device of claim 8, wherein a second portion of the gate dielectric is in contact with the first nanostructure, wherein a second portion of the spacer is in contact with the second portion of the gate dielectric, and wherein a second portion of the dielectric layer is between the second portion of the gate dielectric and the second portion of the spacer in a top-down view.

13. The semiconductor device of claim 8, wherein the dielectric layer comprises silicon oxide.

14. A method of forming a semiconductor device, the method comprising:
forming a first nanostructure over a substrate;
forming a dummy gate structure over the substrate, wherein the dummy gate structure comprise a dummy gate and a dummy gate dielectric, and wherein the dummy gate dielectric is in contact with the first nanostructure;
converting a first portion of the dummy gate at a sidewall of the dummy gate to a dielectric layer;
removing a remaining portion of the dummy gate structure to form a first opening; and
forming a gate structure in the first opening, wherein the gate structure comprises a gate electrode and a gate dielectric, and wherein the gate dielectric is in contact with the first nanostructure and the dielectric layer.

15. The method of claim 14, wherein converting the first portion of the dummy gate at the sidewall of the dummy gate to the dielectric layer comprises performing an annealing process with oxygen gas.

16. The method of claim 15, wherein the annealing process is performed further with oxygen plasma.

17. The method of claim 14, wherein the dielectric layer and the gate dielectric comprise different materials.

18. The method of claim 14, wherein the dummy gate comprises polycrystalline silicon and the dielectric layer comprises silicon oxide.

19. The method of claim 14, wherein a first portion of the gate dielectric is in contact with the first nanostructure, wherein a first portion of the dielectric layer is in contact with the first portion of the gate dielectric, and wherein the first portion of the dielectric layer has a shape of a bow in a top-down view.

20. The method of claim 19, wherein the first portion of the dielectric layer is separated from the first nanostructure by the first portion of the gate dielectric.
